(19) United States
(12) Patent Application Publication
(10) Pub. No.: US 2026/0282336 A1
(43) Pub. Date: Sep. 17, 2026

(54) RECESS GATE AND INTERCONNECTOR STRUCTURE AND METHOD FOR PREPARING THE SAME

(71) Applicant: NANYA TECHNOLOGY CORPORATION, NEW TAIPEI CITY (TW)

(72) Inventor: PING HSU, NEW TAIPEI CITY (TW)

(21) Appl. No.: 19/081,175

(22) Filed: Mar. 17, 2025

(51) Int. Cl. H10B 12/00

(52) U.S. Cl. CPC H10B 12/485; H10B 12/0335; H10B 12/053; H10B 12/315; H10B 12/34

(57) ABSTRACT

The present application provides a semiconductor device and a method for preparing the same. The semiconductor device includes a substrate having an active region; a recess gate structure disposed in the substrate and intersecting the active region; a bit line contact including a polysilicon stack and disposed on the substrate; a conductive pillar disposed over the substrate and electrically connected to the active region; a landing pad disposed on the conductive pillar and electrically connected to the conductive pillar; and a stack of dielectric layers disposed over the substrate and laterally surrounding the bit line contact. The polysilicon stack includes a first polysilicon layer and a second polysilicon layer disposed over the first polysilicon layer. The second polysilicon layer is in direct contact with the stack of dielectric layers.

### TECHNICAL FIELD

The present disclosure relates to a semiconductor device and a method for manufacturing the device, and more particularly, to a semiconductor device having a recess gate and an interconnector structure, and a method for manufacturing the same.

### DISCUSSION OF THE BACKGROUND

The semiconductor industry has developed over the years to create devices with better performance at competitive or lower costs. Such developments have resulted in the continuous reduction of scale of semiconductor devices, which has been realized by numerous and mutually-supportive advances in semiconductor manufacturing processes, along with advances in materials and new device designs.

Dynamic random-access memory (DRAM) is a type of semiconductor device composed of an array of memory cells, each consisting of a field-effect transistor and a capacitor. The field-effect transistor enables access to the capacitor, which is configured for data storage. As DRAM is scaled down, space between adjacent memory cells decreases significantly. As a result, parasitic capacitance between adjacent memory cells increases, and this rise in parasitic capacitance limits DRAM operation speeds.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate having an active region; a recess gate structure disposed in the substrate and intersecting the active region; a bit line contact comprising a polysilicon stack and disposed on the substrate; a conductive pillar disposed over the substrate and electrically connected to the active region; a landing pad disposed on the conductive pillar and electrically connected to the conductive pillar; and a stack of dielectric layers disposed over the substrate and laterally surrounding the bit line contact. The polysilicon stack comprises a first polysilicon layer and a second polysilicon layer disposed over the first polysilicon layer. The second polysilicon layer is in direct contact with the stack of dielectric layers.

Another aspect of the present disclosure provides a semiconductor device including a substrate having an active region; a stack of dielectric layers disposed over the substrate, wherein the stack of dielectric layers comprises a first dielectric layer, a second dielectric layer disposed over the first dielectric layer, a third dielectric layer disposed over the second dielectric layer, and a fourth dielectric layer disposed over the third dielectric layer; a recess gate structure disposed in the substrate and intersecting the active region; a bit line contact disposed on the substrate and laterally surrounded by the stack of dielectric layers; a capacitor contact disposed in the substrate and protruding from the first dielectric layer of the stack of dielectric layers; and a landing pad disposed over the capacitor contact.

Another aspect of the present disclosure provides a method of fabricating a semiconductor device including providing a substrate having an active region; providing a recess gate structure in the active region of the substrate; forming a stack of dielectric layers over the substrate; forming a bit line contact on the substrate and laterally surrounded by the stack of dielectric layers; forming a capacitor contact in the substrate and protruding from the substrate; and forming a landing pad over the capacitor contact. The capacitor contact comprises a contact structure, a barrier layer, and a barrier spacer.

Another aspect of the present disclosure provides a method of fabricating a semiconductor device including providing substrate having an active region; providing a recess gate structure in the active region of the substrate; forming a stack of dielectric layers over the substrate; forming a bit line contact on the substrate and laterally surrounded by the stack of dielectric layers; forming a capacitor contact in the substrate and protruding from a top surface of the substrate; and forming a landing pad disposed over the capacitor contact.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed herein may be readily utilized as a basis for modifying or designing other structures or processes for carrying out the purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a schematic plan view of a semiconductor device in accordance with some embodiments of the present disclosure.

FIG. 1B is a schematic cross-sectional view along a line A-A′ in FIG. 1A.

FIG. 1C is a schematic cross-sectional view along a line B-B′ in FIG. 1A.

FIG. 1D is a schematic cross-sectional view of a semiconductor device in accordance with alternative embodiments of the present disclosure.

FIG. 1E is a schematic cross-sectional view of a semiconductor device in accordance with alternative embodiments of the present disclosure.

FIG. 1F is a schematic cross-sectional view of a semiconductor device in accordance with alternative embodiments of the present disclosure.

FIG. 1G is a schematic cross-sectional view of a semiconductor device in accordance with alternative embodiments of the present disclosure.

FIG. 1H is a schematic cross-sectional view of a semiconductor device in accordance with alternative embodiments of the present disclosure.

FIG. 1I is a schematic cross-sectional view of a semiconductor device in accordance with alternative embodiments of the present disclosure.

FIG. 1J is a schematic cross-sectional view of a semiconductor device in accordance with alternative embodiments of the present disclosure.

FIG. 2 is a flow diagram illustrating a manufacturing method of a semiconductor device in accordance with some embodiments of the present disclosure.

FIGS. 3A to 3N are schematic cross-sectional views of intermediate structures of the semiconductor device in accordance with the method in FIG. 2.

FIGS. 3O to 3R are schematic cross-sectional views of intermediate structures of the semiconductor device at the stage illustrated in step S15 of the method in FIG. 2 in accordance with alternative embodiments of the present disclosure.

FIG. 4 is another schematic cross-sectional view of the intermediate structure of the semiconductor device at the stage illustrated in FIG. 3J.

FIGS. 5A to 5F are schematic cross-sectional views of intermediate structures of the semiconductor device at the stage illustrated in step S19 of the method in FIG. 2 in accordance with alternative embodiments of the present disclosure.

FIGS. 5G to 5S are schematic cross-sectional views of intermediate structures of the semiconductor device at the stage illustrated in step S23 of the method in FIG. 2 in accordance with alternative embodiments of the present disclosure.

FIGS. 5T to 5Y are schematic cross-sectional views of intermediate structures of the semiconductor device at the stage illustrated in step S19 of the method in FIG. 2 in accordance with alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

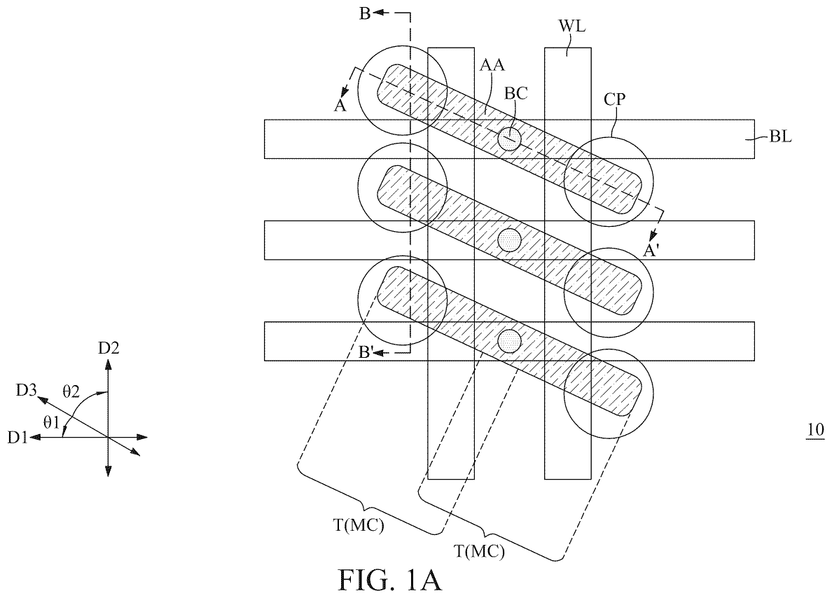

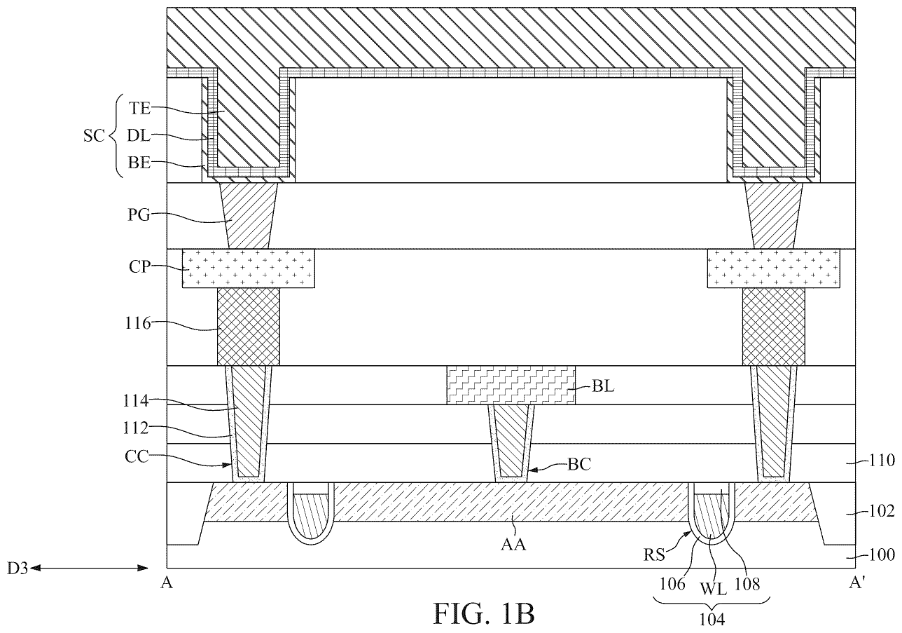

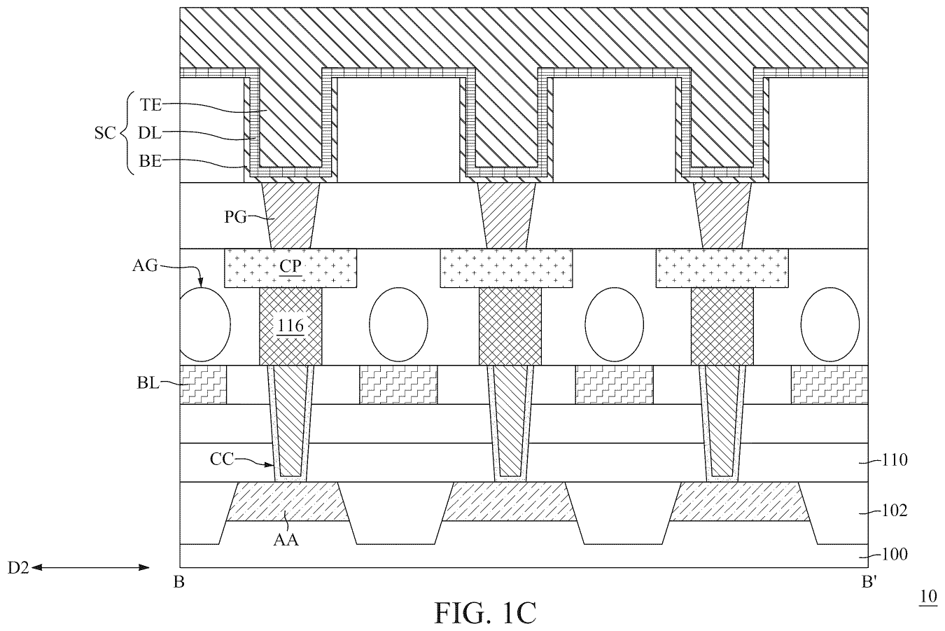

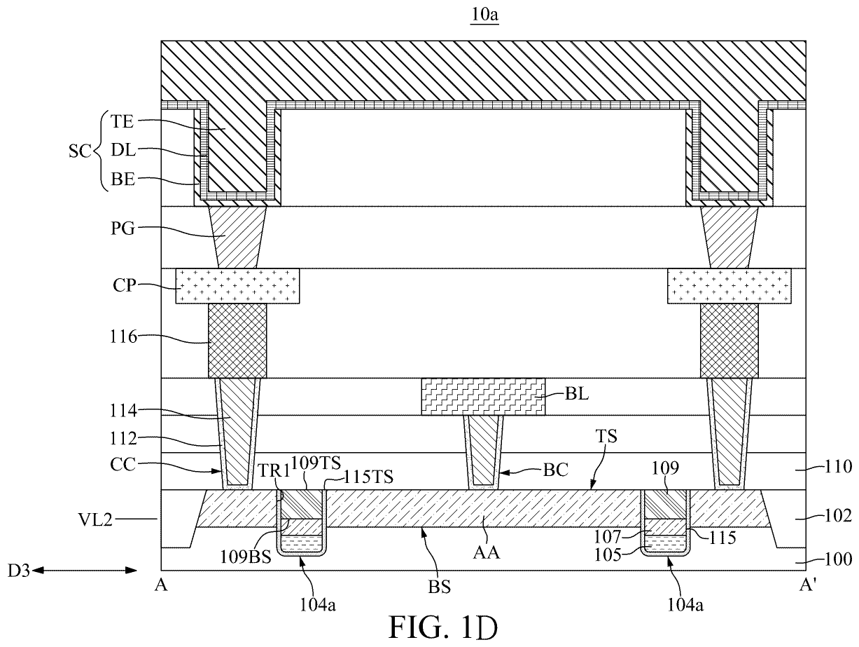

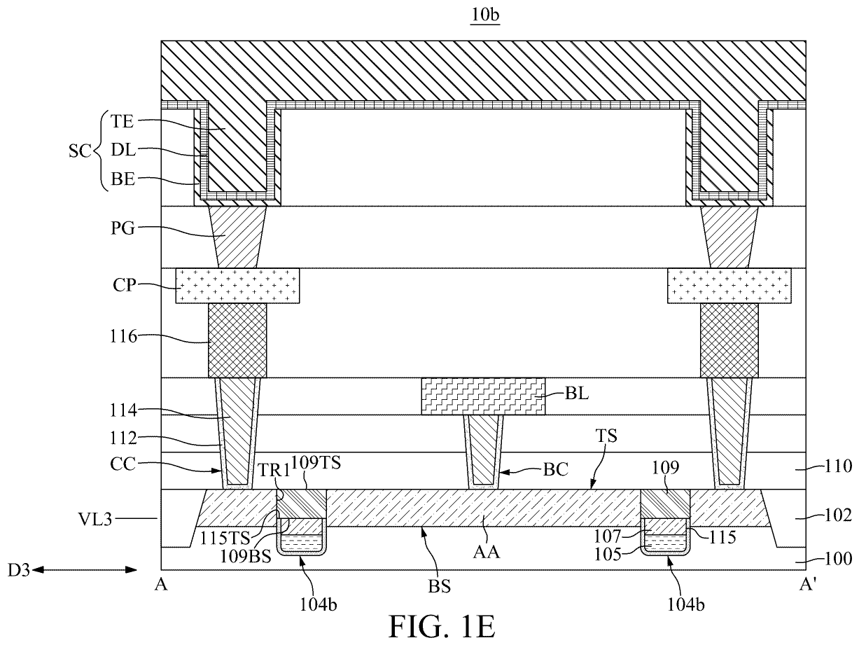

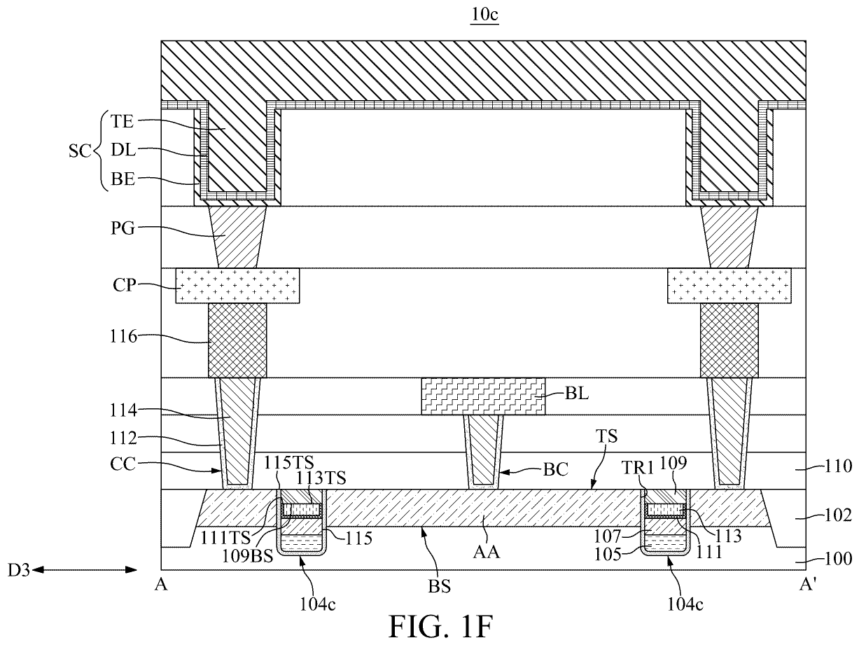

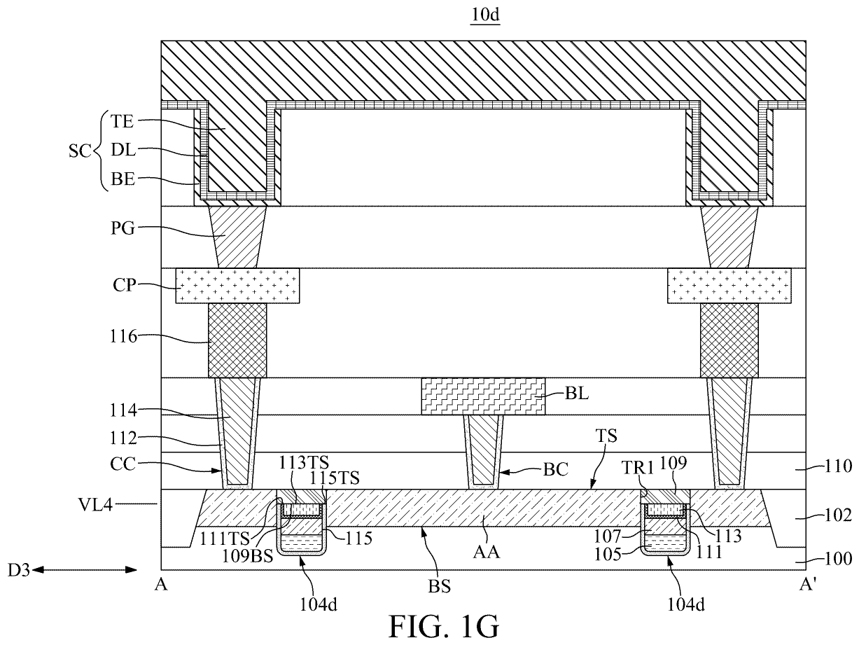

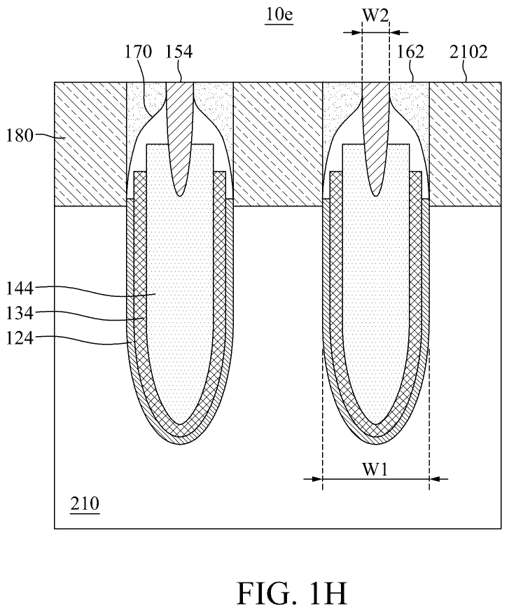

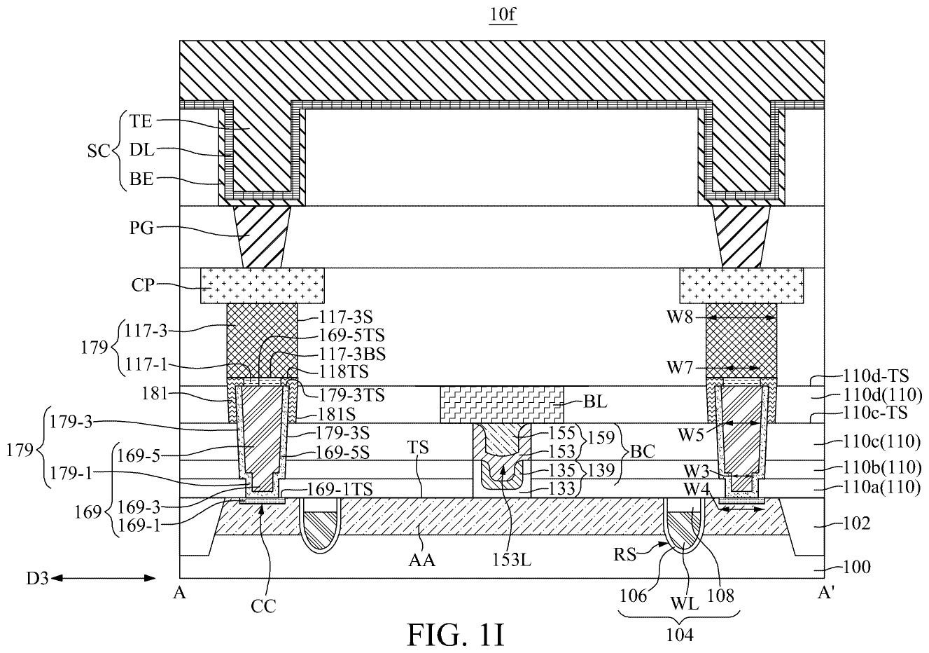

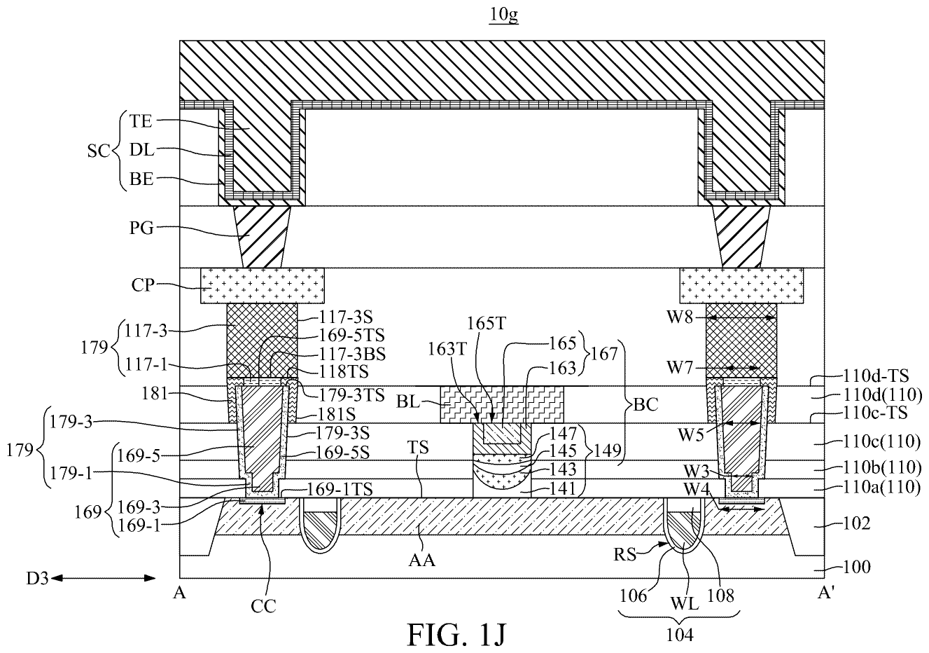

FIG. 1A is a schematic plan view of a semiconductor device 10 in accordance with some embodiments of the present disclosure. FIG. 1B is a schematic cross-sectional view along a line A-A′ in FIG. 1A. FIG. 1C is a schematic cross-sectional view along a line B-B′ shown in FIG. 1A. It should be noted that some elements shown in FIG. 1B and FIG. 1C (e.g., a substrate 100, an isolation structure 102, interlayer dielectric layers 110, capacitor contacts CC, conductive pillars 116, capacitor plugs PG, air gaps AG, and a storage capacitor SC) are omitted from FIG. 1A.

Referring to FIG. 1A, in some embodiments, the semiconductor device 10 is a dynamic random-access memory (DRAM) device. The semiconductor device 10 includes an array of memory cells MC. It should be noted that, for conciseness, only two columns of memory cells MC are depicted in FIG. 1A. The array of memory cells MC includes active regions AA, word lines WL and bit lines BL. Each memory cell MC consists of a field-effect transistor T and the storage capacitor SC (not shown in FIG. 1A) connected to the field-effect transistor T. The field-effect transistor T is defined in the vicinity where one of the active regions AA intersects one of the word lines WL. A portion of the word line WL intersecting the active region AA functions as a gate terminal of the field-effect transistor T, and portions of the active region AA at opposite sides of the word line WL function as source and drain terminals of the field-effect transistor T. One of the source and drain terminals is electrically connected to one of the bit lines BL (e.g., through a bit line contact BC). In addition, other source and drain terminals are electrically connected to the storage capacitor SC (shown in FIG. 1B). In some embodiments, a landing pad CP is formed between the capacitor SC and the underlying source terminal or drain terminal of the field-effect transistor T. In addition, in some embodiments, each active region AA is shared by two of the memory cells MC. In such embodiments, each active region AA intersects two of the word lines WL, and the two field-effect transistors T sharing a same active region AA are connected by a common source or drain terminal, which is electrically connected to one of the bit lines BL.

The word lines WL extend along a direction D2, and the bit lines BL extend along a direction D1, wherein the direction D1 and the direction D2 are nonparallel. In some embodiments, the direction D1 is perpendicular to the direction D2. In addition, in some embodiments, the active regions AA extend along a direction D3, wherein the direction D1 and the direction D3 are nonparallel, and the direction D2 and the direction D3 are nonparallel. However, those skilled in the art can recognize that an angle θ1 between the directions D1 and D3, and an angle θ2 between the directions D2 and D3, can be adjusted according to design requirements, and the present disclosure is not limited thereto. In addition, those skilled in the art can recognize that the directions of the components shown in FIG. 1A may be rearranged based on process and design requirements, and the present disclosure is not limited thereto.

Referring to FIGS. 1A and 1B, the active region AA is a region of the substrate 100. The substrate 100 may be a semiconductor wafer or a semiconductor-on-insulator (SOI) wafer. For example, a material of the semiconductor wafer or the SOI wafer may include silicon. In some embodiments, the active region AA of the substrate 100 is a region doped with first conductive type (e.g., n-type) dopants or doped with second conductive type (e.g., p-type) dopants, wherein the second conductive type is complementary to the first conductive type. As mentioned above, portions of each active region AA at opposite sides of the intersecting word line WL function as the source and drain terminals of the corresponding field-effect transistor T.

The active regions AA are electrically isolated from one another by the isolation structure 102. In some embodiments, the isolation structure 102 is formed in a recess at a surface of the substrate 100, and is made of an insulating material. In such embodiments, the isolation structure 102, which may also be referred to as a trench isolation structure, extends from the surface of the substrate 100 into the substrate 100. A depth of the isolation structure 102 may be greater than a depth of the active region AA, and the active regions AA are laterally separated from one another by the isolation structure 102. It should be noted that the isolation structure 102 extends between the active regions AA, and what appears in FIG. 1B to be multiple portions of the isolation structure 102 may actually be connected to one another.

In some embodiments, the word lines WL are formed in recess gate structures 104, respectively. The recess gate structures 104 extend along the direction D2 (shown in FIG. 1A) and intersect the active regions AA (as shown in FIG. 1B). In some embodiments, each active region AA intersects two of the recess gate structures 104. As shown in FIG. 1B, the recess gate structures 104 are respectively disposed in a recess RS at the surface of the substrate 100. A depth of the recess RS may be greater than the depth of the active region AA and may be greater than, equal to, or less than the depth of the isolation structure 102. In some embodiments, the recess gate structures 104 respectively include a gate dielectric layer 106, one of the word lines WL and an insulating capping layer 108. The gate dielectric layer 106 conformally covers a surface of the recess RS, and an inner surface of the gate dielectric layer 106 defines a recess corresponding to the recess RS of the substrate 100. The word line WL is deposited in the recess defined by the inner surface of the gate dielectric layer 106, at a height lower than the surface of the substrate 100. The insulating capping layer 108 covers a top surface of the word line WL and extends vertically to a height that aligns substantially with the surface of the substrate 100. In other words, the recess defined by the inner surface of the gate dielectric layer 106 is filled with the word line WL and the insulating capping layer 108.

In some embodiments, the gate dielectric layer 106 is formed of a dielectric material. For example, the dielectric material may include silicon oxide or a high-k dielectric material with a dielectric constant greater than 3.9 (e.g., hafnium silicate, zirconium silicate, hafnium oxide, zirconium oxide, or the like). In addition, in some embodiments, the word line WL may be made of polysilicon, a metal material (e.g., tungsten) or a metal silicide (e.g., nickel silicide, platinum silicide, titanium silicide, molybdenum silicide, cobalt silicide, tantalum silicide, tungsten silicide or the like). Further, in some embodiments, the insulating capping layer 108 may be made of an insulating material, such as silicon oxide, silicon nitride, silicon oxynitride, or the like.

A stack of interlayer dielectric layers 110 is formed over the substrate 100, covering the active regions AA, the isolation structure 102 and the recess gate structures 104. In addition, the bit line contacts BC and the capacitor contacts CC are formed in the stack of interlayer dielectric layers 110. The bit line contacts BC and the capacitor contacts CC respectively penetrate through the bottommost layers of the interlayer dielectric layers 110 to establish electrical contact with the active regions AA. Each of the bit line contacts BC may be connected to a portion of the corresponding active region AA that is located between two of the word lines WL intersecting such active region AA. In other words, the bit line contacts BC are electrically connected to the common source/drain terminals of the transistors T (as shown in FIG. 1A). In contrast, the capacitor contacts CC are electrically connected to another source/drain terminal of each transistor T, such that each of the word lines WL is positioned between one of the bit line contacts BC and one of the capacitor contacts CC. The bit line contacts BC are electrically connected to the bit lines BL, while the capacitor contacts CC are electrically connected to storage capacitors (e.g., the storage capacitors SC, described below). In some embodiments, the bit lines BL are formed at a height lower than a height of the storage capacitors SC. In such embodiments, the bit line contacts BC may be shorter than the capacitor contacts CC, and top ends of the bit line contacts BC may be lower than top ends of the capacitor contacts CC. For example, the bit line contacts BC penetrate through the two bottommost interlayer dielectric layers 110, while the capacitor contacts CC penetrate through the three bottommost interlayer dielectric layers 110. Furthermore, in some embodiments, the bit line contacts BC and the capacitor contacts CC respectively include a conductive pillar 114 and a barrier layer 112 covering a sidewall and a bottom surface of the conductive pillar 114.

In some embodiments, the interlayer dielectric layers 110 may be made of a dielectric material. For example, the dielectric material may include silicon nitride, silicon oxide, silicon oxynitride, undoped silica glass, borosilica glass, phosphosilica glass, borophosphosilica glass, or a combination thereof. In addition, the conductive pillars 114 of the bit line contacts BC and the capacitor contacts CC may be made of aluminum, copper, tungsten, cobalt, another suitable metal or a metal alloy, and the barrier layer 112 of the bit line contacts BC and the capacitor contacts CC may be made of, for example, tungsten nitride.

The bit lines BL cover and electrically connect to the bit line contacts BC. Although not shown, each of the bit lines BL may cover the bit line contacts BC electrically connected to a row of transistors T, and each of the bit lines BL may extend along the direction D1. As shown in FIG. 1B, the bit lines BL may be formed in one of the interlayer dielectric layers 110 above the bit line contacts BC. In some embodiments, topmost portions of the capacitor contacts CC and the bit lines BL are located in a same interlayer dielectric layer 110. In such embodiments, top surfaces of the bit lines BL may be substantially coplanar with top surfaces of the capacitor contacts CC. In alternative embodiments, the bit line contacts BC are much shorter than the capacitor contacts CC, and the top surfaces of the bit lines BL may be lower than the top surfaces of the capacitor contacts CC. In addition, in some embodiments, the bit lines BL are made of a conductive material. For example, the conductive material may include aluminum, copper, tungsten, cobalt, another suitable metal, or metal alloys.

Referring to FIGS. 1B and 1C, the conductive pillars 116 and the landing pads CP are disposed on the capacitor contacts CC. Each of the conductive pillars 116 stands on one of the capacitor contacts CC and is covered by one of the landing pads CP. A vertical height of the conductive pillar 116 may be greater than a vertical height (or a thickness) of the landing pad CP. In some embodiments, a sidewall of each conductive pillar 116 is laterally recessed from a sidewall of the overlying landing pad CP. In such embodiments, each conductive pillar 116 has a footprint area smaller than a footprint area of the corresponding landing pad CP. In addition, the conductive pillars 116 may be entirely overlapped by the landing pads CP. The conductive pillars 116 and the landing pads CP may be formed in a same interlayer dielectric layer 110 covering the capacitor contacts CC. In embodiments where the top surfaces of the bit lines BL are coplanar with or lower than the top surfaces of the capacitor contacts CC, the bit lines BL are also disposed below the conductive pillars 116 and the landing pads CP. As shown in FIG. 1C, a distance between adjacent landing pads CP is less than a distance between adjacent conductive pillars 116. As a consequence, when the interlayer dielectric layer 110 is deposited in the spaces between the adjacent landing pads CP and the spaces between the adjacent conductive pillars 116, the smaller spaces between the adjacent landing pads CP may be filled sooner than the larger spaces between the adjacent conductive pillars 116. Accordingly, air gaps AG may be formed and sealed in the larger spaces (i.e., in the spaces between the adjacent conductive pillars 116). In some embodiments, the air gaps AG may not expose sidewalls of the conductive pillars 116, and may not expose the top surfaces of the underlying bit lines BL. However, in alternative embodiments, at least some portions of the sidewalls of the conductive pillars 116 and/or at least some portions of the top surfaces of the bit lines BL are exposed by the air gaps AG. In addition, in certain embodiments, top ends of the air gaps AG may extend to the spaces between the landing pads CP. Further, although the air gaps AG are depicted as oval shapes in FIG. 1C, the air gaps AG can be formed into other shapes, and the present disclosure is not limited thereto.

The landing pads CP and the conductive pillars 116 are made of different conductive materials. In some embodiments, a resistivity of the conductive material for forming the landing pads CP is less than a resistivity of the conductive material for forming the conductive pillars 116, and the conductive material for forming the conductive pillars 116 has a sufficient etching selectivity with respect to the conductive material.

The landing pads CP and the conductive pillars 116 may each be formed by an etching process. In some embodiments, the landing pads CP may be formed by a first etching process. In some embodiments, the conductive pillars 116 may be formed by a second etching process that follows the first etching process.

In some embodiments, the capacitor plugs PG stand on the landing pads CP, respectively. The capacitor plugs PG may be formed in one of the interlayer dielectric layers 110 covering the landing pads CP. Since each of the landing pads CP has a footprint area greater than a footprint area of the underlying conductive pillar 116, connection between the capacitor plugs PG and the conductive pillars 116 can be established even when the capacitor plugs PG are offset from the conductive pillars 116. In other words, due to the landing pads CP, electrical connection between the capacitor plugs PG and the conductive pillars 116 can be ensured. In addition, as described above, the air gaps AG can be formed as a result of disposing the landing pads CP. The capacitor plugs PG are made of a conductive material. For example, such conductive material may include aluminum, copper, tungsten, cobalt, and other suitable metals or metal alloys.

The storage capacitors SC are disposed on and electrically connected to the capacitor plugs PG, respectively. In some embodiments, the interlayer dielectric layer 110 above the capacitor plugs PG may have openings overlapping the capacitor plugs PG, and the storage capacitor SC may fill the openings and may cover a top surface of the interlayer dielectric layer 110. The storage capacitors SC may include bottom electrodes BE, a dielectric layer DL and a top electrode TE. The bottom electrodes BE conformally cover a sidewall and a bottom surface of each opening in the interlayer dielectric layer 110 above the capacitor plugs PG. The bottom electrodes BE are separated from one another, and are respectively in electrical connection with one of the capacitor plugs PG. The dielectric layer DL conformally covers surfaces of the bottom electrodes BE and the top surface of the interlayer dielectric layer 110 in which the bottom electrodes BE are disposed. The top electrode TE fills the openings of the aforementioned interlayer dielectric layer 110 and may extend onto a topmost surface of the interlayer dielectric layer 110. In the embodiments described above, the dielectric layer DL and the top electrode TE are shared by the storage capacitors SC (i.e., the dielectric layer DL and the top electrode TE extend across multiple storage capacitors SC). The bottom electrodes BE and the top electrode TE are made of conductive materials, while the dielectric layer DL may be made of a high-k dielectric material. For example, the conductive materials for forming the bottom electrodes BE may include doped polysilicon, metal silicide, aluminum, copper or tungsten, while the conductive materials for forming the top electrode TE may include doped polysilicon, copper, or aluminum. In addition, the high-k dielectric material for forming the dielectric layer DL may include barium strontium titanate, lead zirconium titanate, titanium oxide, aluminum oxide, hafnium oxide, yttrium oxide, zirconium oxide, or the like.

Referring to FIGS. 1A to 1C, in some embodiments, the storage capacitors SC are electrically connected to the transistors T through the capacitor plugs PG, the landing pads CP, the conductive pillars 116 and the capacitor contacts CC. As shown in FIGS. 1A and 1C, as a size of each memory cell MC decreases, a distance between adjacent memory cells MC along the direction D2 may also be reduced. As a result, parasitic capacitance between adjacent conductive pillars 116 is increased, leading to a greater resistance-capacitance (RC) delay in the semiconductor device 10. As described above, by forming the landing pads CP to be larger than the underlying conductive pillar 116, the air gaps AG can be formed between adjacent conductive pillars 116. Air sealed in the air gaps AG has a dielectric constant of approximately 1, which is significantly lower than a dielectric constant of a solid dielectric material (i.e., the dielectric material used for forming the interlayer dielectric layers 110). Therefore, the parasitic capacitance between the conductive pillars 116 can be reduced by the formation of the air gaps AG, and the RC delay of the semiconductor device 10 can be effectively decreased.

FIG. 1D is a schematic cross-sectional view of a semiconductor device 10a in accordance with alternative embodiments of the present disclosure. The semiconductor device 10a is similar to the semiconductor device 10 in many aspects, and description of similar features are not repeated.

Referring to FIG. 1D, the semiconductor device 10a includes recess gate structures 104a. Each of the recess gate structures 104a comprises a gate insulating layer 115, a work function layer 105, a first conductive layer 107, and a capping layer 109.

In some embodiments, the gate insulating layer 115 is conformally formed in a trench TR1 disposed in the substrate 100. A top surface 115TS of the gate insulating layer 115 is substantially coplanar with a top surface TS of the substrate 100. The gate insulating layer 115 may have a thickness in a range of about 1 nm to about 7 nm, including about 1 nm, about 2 nm, about 3 nm, about 4 nm, about 5 nm, about 6 nm, or about 7 nm. In some embodiments, the gate insulating layer 115 may be formed by a thermal oxidation process. For example, the gate insulating layer 115 may be formed by oxidizing a surface of the trench TR1. In some embodiments, the gate insulating layer 115 may be formed by a deposition process such as a chemical vapor deposition or an atomic layer deposition. The gate insulating layer 115 may include a high-k material, an oxide, a nitride, an oxynitride, or a combination thereof.

In some embodiments, the work function layer 105 may be formed on the gate insulating layer 115 and in the trench TR1. The work function layer 105 may be formed by a deposition process and a subsequent etch-back process. In some embodiments, the work function layer 105 may be formed of, for example, doped polycrystalline silicon, doped polycrystalline germanium, or doped polycrystalline silicon germanium. In some embodiments, the work function layer 105 may include silicon and/or germanium with substantially no oxygen and no nitrogen. As used in this regard, a feature with “substantially no oxygen and no nitrogen” has less than 2%, less than 1% or less than 0.5% oxygen, and less than 2%, less than 1% or less than 0.5% nitrogen on an atomic basis. In some embodiments, the work function layer 105 may consist essentially of silicon, germanium, or silicon germanium. As used herein, “consist essentially of” with respect to the composition of a layer means that the stated elements compose greater than 95%, greater than 98%, greater than 99% or greater than 99.5% of the stated material on an atomic basis. In some embodiments, the work function layer 105 may be formed of a material having etching selectivity to the substrate 100.

In some embodiments, the first conductive layer 107 may be formed on the work function layer 105 and in the trench TR1. In some embodiments, the first conductive layer 107 may be formed of, for example, germanium. In some embodiments, the first conductive layer 107 may include an atomic percentage of germanium greater than or equal to 50%. In some embodiments, the first conductive layer 107 may be formed by a deposition process. In some embodiments, the deposition process may include a reactive gas including a germanium precursor and/or hydrogen gas.

In some embodiments, the capping layer 109 may be formed on the first conductive layer 107 and in the trench TR1. A top surface 109TS of the capping layer 109 and the top surface 115TS of the gate insulating layer 115 may be substantially coplanar. A bottom surface 109BS of the capping layer 109 may be at a vertical level VL2 higher than a bottom surface BS of the active regions AA. In some embodiments, the capping layer 109 is formed of germanium oxide. In some embodiments, the capping layer 109 may be formed by, for example, chemical vapor deposition, atomic layer deposition, or another applicable deposition process.

FIG. 1E is a schematic cross-sectional view of a semiconductor device 10b in accordance with alternative embodiments of the present disclosure. The semiconductor device 10b may have a structure similar to that illustrated in FIG. 1D. Elements in FIG. 1E that are same as or similar to elements in FIG. 1D are indicated with similar reference numbers and duplicative descriptions are omitted.

Referring to FIG. 1E, the semiconductor device 10b includes recess gate structures 104b. Each of the recess gate structures 104b comprises a gate insulating layer 115, a work function layer 105, a first conductive layer 107, and a capping layer 109. A top surface 115TS of the gate insulating layer 115 may be at a vertical level VL3 higher than a bottom surface BS of the active region AA. In some embodiments, the top surface 115TS of the gate insulating layer 115 and a bottom surface 109BS of the capping layer 109 may be substantially coplanar. In some embodiments, the top surface 115TS of the gate insulating layer 115 may not be substantially coplanar with the bottom surface 109BS of the capping layer 109.

FIG. 1F is a schematic cross-sectional view of a semiconductor device 10c in accordance with alternative embodiments of the present disclosure. The semiconductor device 10c may have a structure similar to that illustrated in FIG. 1D. Elements in FIG. 1F that are same as or similar to elements in FIG. 1D are indicated with similar reference numbers and duplicative descriptions are omitted.

Referring to FIG. 1F, the semiconductor device 10c includes recess gate structures 104c. Each of the recess gate structures 104c comprises a gate insulating layer 115, a work function layer 105, a first conductive layer 107, a liner layer 111, a second conductive layer 113, and a capping layer 109.

In some embodiments, the liner layer 111 may be conformally disposed on the first conductive layer 107 and the gate insulating layer 115, and disposed between the capping layer 109 and the first conductive layer 107. The liner layer 111 may have a U-shaped cross-sectional profile. A top surface 111TS of the liner layer 111 may be substantially coplanar with a bottom surface 109BS of the capping layer 109. The second conductive layer 113 may be disposed between the capping layer 109 and the liner layer 111. A top surface 113TS of the second conductive layer 113 and the bottom surface 109BS of the capping layer 109 may be substantially coplanar.

In some embodiments, the liner layer 111 may be formed of a material having an etching selectivity to the gate insulating layer 115. In some embodiments, the liner layer 111 may be formed of a material having an etching selectivity to the first conductive layer 107. In some embodiments, the liner layer 111 may be formed of a material having an etching selectivity to the substrate 100. In some embodiments, the liner layer 111 may be formed of, for example, a material including sp² hybridized carbon atoms. In some embodiments, the liner layer 111 may be formed of, for example, a material including carbons having hexagonal crystal structures. In some embodiments, the liner layer 111 may be formed of, for example, graphene, graphite, or the like.

In some embodiments, the liner layer 111 may be formed on a catalyst substrate and then transferred onto the first conductive layer 107. The catalyst substrate may include nickel, copper, cobalt, platinum, silver, ruthenium, iridium, palladium, an alloy of iron and nickel, an alloy of copper and nickel, an alloy of nickel and molybdenum, an alloy of gold and nickel, or an alloy of cobalt and copper.

In some embodiments, the second conductive layer 113 may be formed of, for example, molybdenum. In some embodiments, the second conductive layer 113 may be formed by a chemical vapor deposition process. For example, an intermediate semiconductor device to be disposed may be exposed to a molybdenum precursor and a reactant. In some embodiments, the reactant may flow continuously and a flow of the molybdenum precursor to the chamber may be turned on and off.

In some embodiments, the molybdenum precursor may include a molybdenum halide. In some embodiments, the molybdenum halide may include molybdenum fluoride, molybdenum chloride, or a combination thereof. In some embodiments, the molybdenum precursor may be flowed using a carrier gas over the intermediate semiconductor device to be disposed. In some embodiments, the carrier gas may flow through an ampoule including the molybdenum precursor. In some embodiments, the carrier gas may be an inert gas. In some embodiments, the inert gas may include one or more of N₂, Ar, and He.

FIG. 1G is a schematic cross-sectional view of a semiconductor device 10d in accordance with alternative embodiments of the present disclosure. The semiconductor device 10d may have a structure similar to that illustrated in FIG. 1F. Elements in FIG. 1G that are same as or similar to elements in FIG. 1F are indicated with similar reference numbers and duplicative descriptions are omitted.

Referring to FIG. 1G, the semiconductor device 10d includes recess gate structures 104d. Each of the recess gate structures 104d comprises a gate insulating layer 115, a work function layer 105, a first conductive layer 107, a liner layer 111, a second conductive layer 113, and a capping layer 109.

In some embodiments, a top surface 115TS of the gate insulating layer 115 may be at a vertical level VL4 higher than a bottom surface BS of the active region AA. In some embodiments, the top surface 115TS of the gate insulating layer 115 and the bottom surface 109BS of the capping layer 109 may be substantially coplanar. In some embodiments, the top surface 115TS of the gate insulating layer 115 may not be substantially coplanar with the bottom surface 109BS of the capping layer 109. In some embodiments, the top surface 115TS of the gate insulating layer 115, a top surface 111TS of the liner layer 111, and a top surface 113TS of the second conductive layer 113 may be substantially coplanar.

FIG. 1H is a schematic cross-sectional view of a semiconductor device 10e in accordance with alternative embodiments of the present disclosure.

Referring to FIG. 1H, the semiconductor device 10e is a recessed access device (RAD) transistor including a substrate 210, a plurality of word lines 144 disposed in the substrate 210 and surrounded by dielectric liners 124, a plurality of insulative plugs 154 disposed in the substrate 210 and extending into the word lines 144, respectively, and a plurality of impurity regions 180 disposed in the substrate 210 and on either side of the word lines 144, wherein the impurity regions 180 serve as source/drain regions of the RAD transistor. The dielectric liners 124, between the substrate 210 and the word lines 144, are employed to prevent junction leakage. In addition, the dielectric liners 124 can prevent dopants introduced in the impurity regions 180 from migrating into the word lines 144.

The semiconductor device 10e further includes an isolation layer 162 disposed in the substrate 210 and employed to cap the word lines 144. In some embodiments, the isolation layer 162 is made of germanium oxide. With high integration of the semiconductor device 10e, a distance between the word lines 144 may be reduced. This may increase parasitic capacitance between the word lines 144, and performance of the semiconductor device 10e may be degraded. Therefore, a plurality of voids 170 that typically hold air, which has a dielectric constant or k value of about 1, can be introduced in the isolation layer 162 to reduce the parasitic capacitance. Thus, a leakage current in the highly integrated semiconductor device 10e may be further reduced, thereby improving the performance of the semiconductor device 10e.

In some embodiments, the void 170, buried in the isolation layer 162, extends around a perimeter of the insulative plug 154. In some embodiments, the void 170 can separate at least a portion of the word line 144 from the isolation layer 162. In some embodiments, the isolation layer 162 capping the word line 144 may include a plurality of voids 170 having a low dielectric constant to reduce the parasitic capacitance. In some embodiments, the insulative plug 154 and the isolation layer 162 can include a same dielectric material if one or more voids 170 are buried in the isolation layer 162. In alternative embodiments, the insulative plug 154 and the isolation layer 162 may include different dielectric materials; the isolation layer 162 can have a first dielectric constant, and the insulative plug 154 can have a second dielectric constant less than the first dielectric constant to further reduce the parasitic capacitance.

As shown in FIG. 1H, the word line 144, below an upper surface 2102 of the substrate 210, and the insulative plug 154 embedded in the word line 144 are concentric. In some embodiments, the word line 144 has a first width W1 (e.g., a top or maximum width), and the insulative plug 154 has a second width W2 (e.g., a top or maximum width) less than the first width W1. In some embodiments, the first width W1 and the second width W2 gradually decrease at positions of increasing distance from the upper surface 2102 of the substrate 210. In some embodiments, the word line 144 is made of germanium. In some embodiments, the semiconductor device 10e may also include a plurality of diffusion barrier liners 134 disposed between the dielectric liners 124 and the word lines 144. The diffusion barrier liners 134 are employed to prevent the word lines 144 from flaking or spalling from the dielectric liners 124.

During manufacturing, a method for manufacturing the semiconductor device 10e may comprise: creating at least one trench in the substrate 210; depositing a conductive material of the word line 144 to partially fill the trench; forming an insulative piece of the insulative plug 154 in the trench, wherein the insulative piece extends into the conductive material; and depositing an isolation material of the isolation layer 162 in the trench to cap the conductive material exposed through the insulative piece, wherein the depositing of the isolation material further comprises enclosing at least one void 170 in the isolation material.

FIG. 1I is a schematic cross-sectional view of a semiconductor device 10f in accordance with alternative embodiments of the present disclosure. The semiconductor device 10f may have a structure similar to that illustrated in FIG. 1B. Elements in FIG. 1I that are same as or similar to elements in FIG. 1B are indicated with similar reference numbers and duplicative descriptions are omitted.

Referring to FIG. 1I, the semiconductor device 10f includes a plurality of bit line contacts BC, a plurality of capacitor contacts CC, and a plurality of conductive pillars 117. For brevity, clarity, and convenience of description, only one bit line contact BC, one capacitor contact CC, and one conductive pillar 117 are described. Additionally, it should be noted that, the interlayer dielectric layer 110 including four dielectric layers 110a, 110b, 110c, and 110d is formed over the substrate 100.

The bit line contacts BC may be disposed in the interlayer dielectric layer 110 (e.g., the dielectric layers 110a, 110b, and 110c) and over the active region AA. In some embodiments, the bit line contact BC may comprise a polysilicon stack 139 disposed over the active region AA and a contact structure 159 disposed directly over the polysilicon stack 139. In some embodiments, the polysilicon stack 139 and the contact structure 159 are surrounded by the interlayer dielectric layer 110 (e.g., the dielectric layers 110a, 110b, and 110c). In some embodiments, the polysilicon stack 139 and the contact structure 159 are disposed between the gate structures 104.

The polysilicon stack 139 includes a first polysilicon layer 133 and a second polysilicon layer 135 disposed over and surrounded by the first polysilicon layer 133. In some embodiments, the second polysilicon layer 135 is separated from the interlayer dielectric layer 110 by the first polysilicon layer 133. It should be noted that, in accordance with some embodiments, the first polysilicon layer 133 is undoped, and the second polysilicon layer 135 is doped. In some embodiments, the second polysilicon layer 135 is doped with arsenic (As), boron (B), or phosphorous (P).

The contact structure 159 includes a barrier layer 153 and a conductive layer 155 disposed over and surrounded by the barrier layer 153. In some embodiments, the barrier layer 153 includes titanium (Ti), titanium nitride (TiN), or a combination thereof, and the conductive layer 155 includes tungsten (W). In some embodiments, the conductive layer 155 is separated from the polysilicon stack 139 by the barrier layer 153. In some embodiments, the barrier layer 153 has a lower portion 153L surrounded by the polysilicon stack 139. In some embodiments, the contact structure 159 is electrically connected to a portion of the corresponding active region AA, which is located between two of the word lines WL that intersect the active region AA through the polysilicon stack 139. In other words, the bit line contact BC is electrically connected to the common source/drain terminal of the transistor T (as shown in FIG. 1A).

Referring to FIG. 1I, in accordance with some embodiments of the present disclosure, the capacitor contact CC may include a contact structure 169, a barrier layer 179, and a barrier spacer 181.

The contact structure 169 may include a lower portion 169-1, a middle portion 169-3, and an upper portion 169-5. The lower portion 169-1 may be disposed in the active region AA and between the isolation structure 102 and the gate structures 104. A top surface 169-1TS of the lower portion 169-1 may be exposed by the top surface TS of the substrate 100. In some embodiments, the top surface 169-1TS is substantially coplanar with the top surface TS of the substrate 100. In some embodiments, the lower portion 169-1 may be made of a conductive material, such as tungsten, cobalt, zirconium, tantalum, titanium, aluminum, ruthenium, copper, metal carbide (e.g., tantalum carbide, titanium carbide, tantalum magnesium carbide), metal nitride (e.g., titanium nitride), transition metal aluminide, or a combination thereof.

The middle portion 169-3 may be disposed on and electrically connected to the lower portion 169-1. The middle portion 169-3 may be at a level higher than a level of the top surface 169-1TS of the lower portion 169-1. A width W3 of the middle portion 169-3 is substantially less than a width W4 of the lower portion 169-1. In some embodiments, the middle portion 169-3 may be made of a conductive material, such as tungsten, cobalt, zirconium, tantalum, titanium, aluminum, ruthenium, copper, metal carbide, metal nitride, transition metal aluminide, or a combination thereof.

The upper portion 169-5 may be disposed on the middle portion 169-3 and may contact the middle portion 169-3. In some embodiments, the upper portion 169-5 may be electrically connected to the lower portion 169-1 through the middle portion 169-3. The upper portion 169-5 may be positioned along the dielectric layers 110a, 110b, and 110c and protruding from a top surface 110c-TS of the dielectric layer 110c. In some embodiments, a top surface 169-5TS of the upper portion 169-5 is substantially coplanar with a top surface 110d-TS of the dielectric layer 110d. In some embodiments, a width W5 of the upper portion 169-5 is greater than the width W3 of the middle portion 169-3. In some embodiments, the width W5 of the upper portion 169-5 is equal to or greater than the width W4 of the lower portion 169-1. In some embodiments, the upper portion 169-5 may be made of a conductive material, such as tungsten, cobalt, zirconium, tantalum, titanium, aluminum, ruthenium, copper, metal carbides, metal nitride, transition metal aluminide, or a combination thereof.

The barrier layer 179 may be disposed between the lower portion 169-1 and the middle portion 169-3, between the interlayer dielectric layer 110 (e.g., the dielectric layer 110a) and the middle portions 169-3, between the interlayer dielectric layer 110 (e.g., the dielectric layers 110b, 110c, and 110d) and the upper portion 169-5. In other words, the barrier layer 179 may include a lower portion 179-1 disposed below a bottom surface of the middle portion 169-3 and surrounding the middle portion 169-3, and an upper portion 179-3 disposed on and directly contact sidewall 169-5S of the upper portion 169-5. In some embodiment, the barrier layer 179 may be made of, for example, titanium, titanium nitride, platinum, nickel, or a combination thereof.

The barrier spacer 181 may be disposed on a sidewall 179-3S of the barrier layer 179, on a top surface 179-3TS of the barrier layer 179, and on the top surface 110c-TS of the dielectric layer 110c. In some embodiments, the barrier spacer 181 may include titanium silicide, nickel silicide, nickel platinum silicide, tantalum silicide, or cobalt silicide.

Referring to FIG. 1I, in accordance with some embodiments of the present, the conductive pillar 117 may include a lower portion 117-1 disposed over the contact structure 169 and between a pair of barrier spacers 181, and an upper portion 117-3 disposed over the lower portion 117-1 and the pair of the barrier spacers 181. In some embodiments, a bottom surface 117-3BS is substantially coplanar with a top surface 181TS of the barrier spacer 181. A sidewall 117-3S of the conductive pillar 117 is substantially coplanar with a sidewall 181S of the barrier spacer 181. In some embodiments, a width W8 of the upper portion 117-3 is greater than a width W7 of the lower portion 117-1. In some embodiments, the lower portion 117-1 may include titanium silicide, nickel silicide, nickel platinum silicide, tantalum silicide, or cobalt silicide. Furthermore, materials of the upper portion 117-3 are same as materials of the conductive pillar 116 illustrated in FIG. 1B, and repeated descriptions are omitted.

FIG. 1J is a schematic cross-sectional view of a semiconductor device 10g in accordance with alternative embodiments of the present disclosure. The semiconductor device 10g may have a structure similar to that illustrated in FIG. 1I. Elements in FIG. 1J that are same as or similar to elements in FIG. 1I are indicated with similar reference numbers and duplicative descriptions are omitted.

Referring to FIG. 1J, the semiconductor device 10g includes a plurality of bit line contacts BC. For brevity, clarity, and convenience of description, only one bit line contact BC is described. The bit line contacts BC may be disposed in the interlayer dielectric layer 110 (e.g., 110a, 110b, and 110c) and over the active region AA. In some embodiments, the bit line contact BC may comprise a polysilicon stack 149 disposed in the dielectric layer 110 and over the active region AA of the substrate 100 and a contact structure 167 disposed directly over the polysilicon stack 149. In some embodiments, the polysilicon stack 149 and the contact structure 167 are surrounded by the dielectric layer 110. In some embodiments, the polysilicon stack 149 and the contact structure 167 are disposed between the gate structures 104.

In some embodiments, the polysilicon stack 149 includes a first polysilicon layer 141, a second polysilicon layer 143 disposed over the first polysilicon layer 141, a third polysilicon layer 145 disposed over the second polysilicon layer 143, and a fourth polysilicon layer 147 disposed over the third polysilicon layer 145. In some embodiments, each of the first polysilicon layer 141, the second polysilicon layer 143, the third polysilicon layer 145 and the fourth polysilicon layer 147 is in direct contact with the dielectric layer 110.

It should be noted that the first polysilicon layer 141 and the third polysilicon layer 145 are undoped, and the second polysilicon layer 143 and the fourth polysilicon layer 147 are doped. In some embodiments, a dopant concentration of the second polysilicon layer 143 is greater than a dopant concentration of the fourth polysilicon layer 147. In some embodiments, the second polysilicon layer 143 and the fourth polysilicon layer 147 are doped with arsenic (As), boron (B), or phosphorous (P). In some embodiments, each of the first polysilicon layer 141, the second polysilicon layer 143 and the third polysilicon layer 145 has a concave top surface facing the contact structure 167. In some embodiments, the first polysilicon layer 141, the second polysilicon layer 143 and the third polysilicon layer 145 have U-shaped or V-shaped profiles.

In addition, in some embodiments, the contact structure 167 includes a barrier layer 163 and a conductive layer 165 disposed over and surrounded by the barrier layer 163. In some embodiments, the barrier layer 163 includes titanium (Ti), titanium nitride (TiN), or a combination thereof, and the conductive layer 165 includes tungsten (W). In some embodiments, the conductive layer 165 is separated from the polysilicon stack 149 by the barrier layer 163. In some embodiments, the contact structure 167 is electrically connected to a source/drain structure through the polysilicon stack 149. In some embodiments, a top surface 163T of the barrier layer 163, a top surface 165T of the conductive layer 165, and the top surface of the dielectric layer 110c are substantially coplanar with each other.

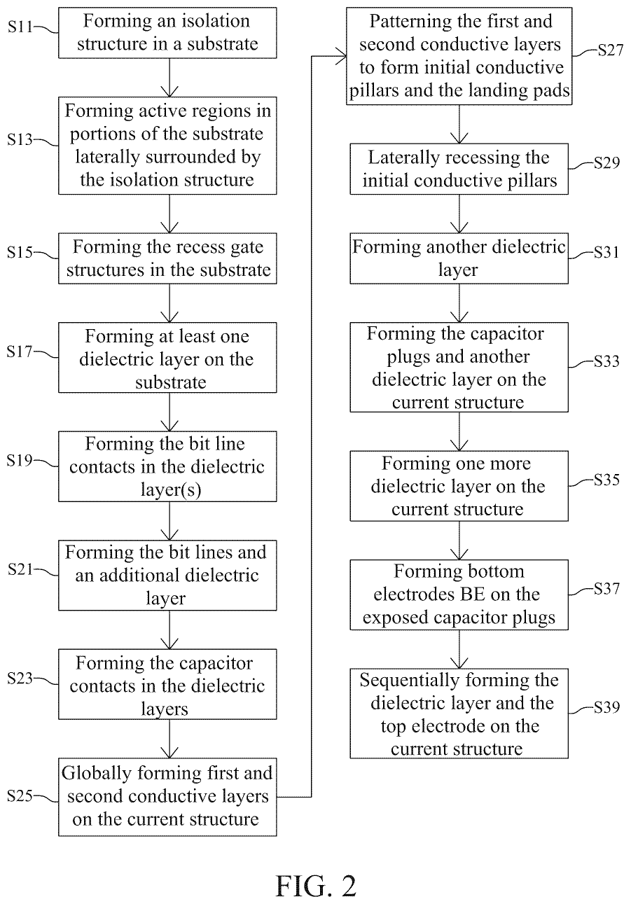

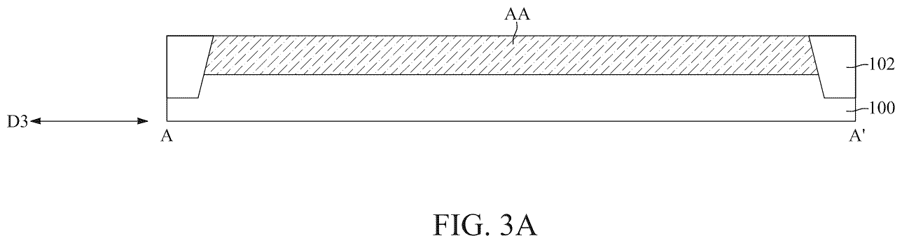

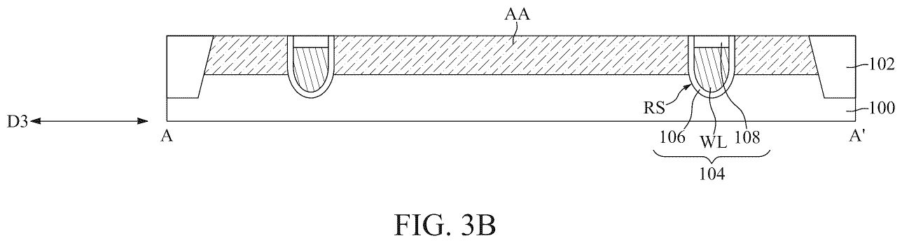

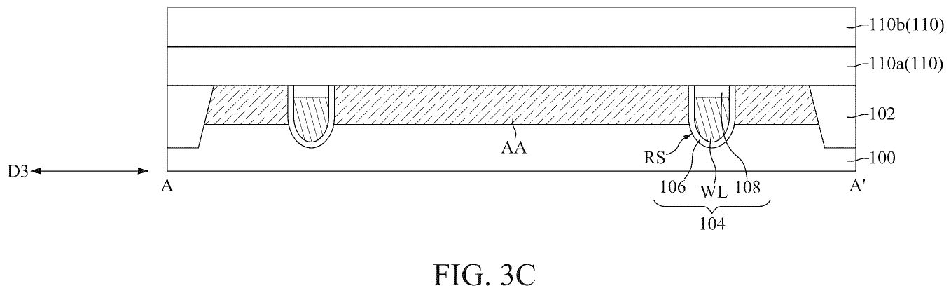

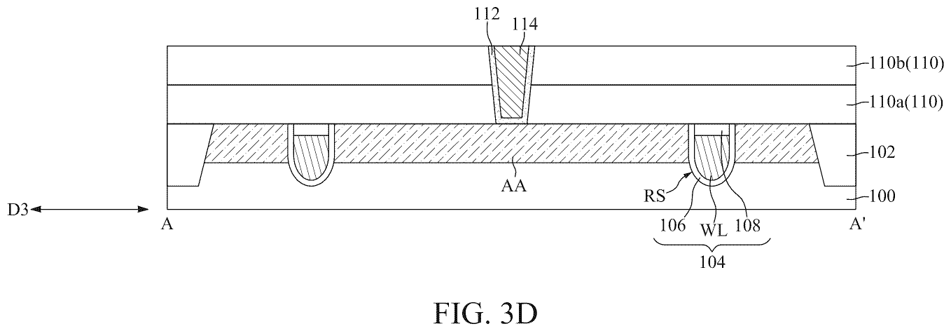

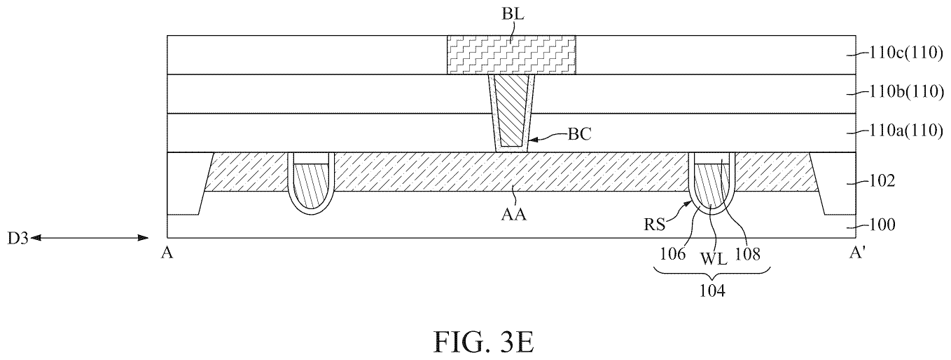

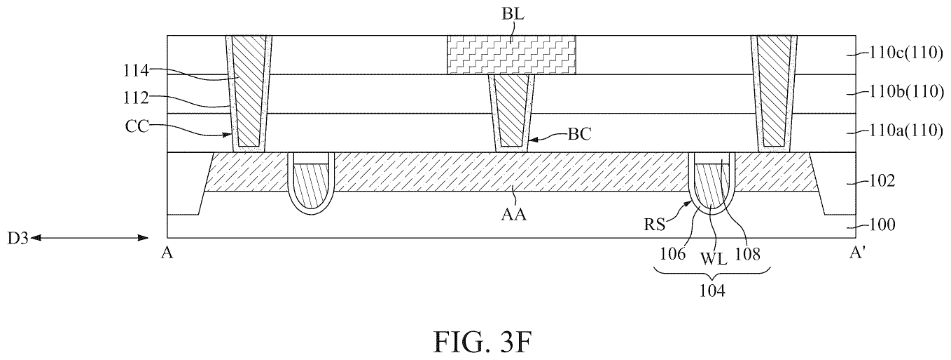

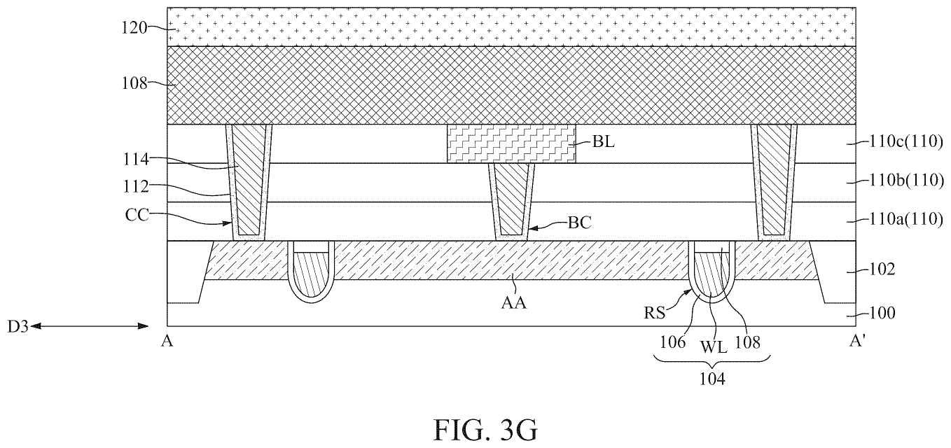

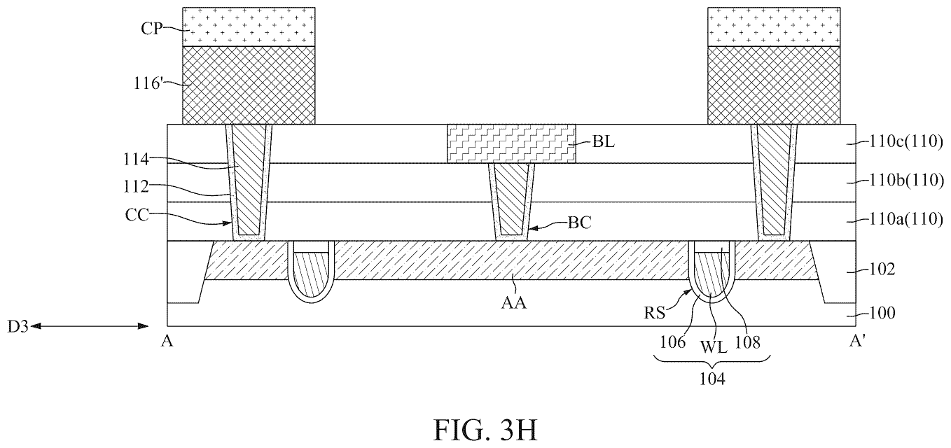

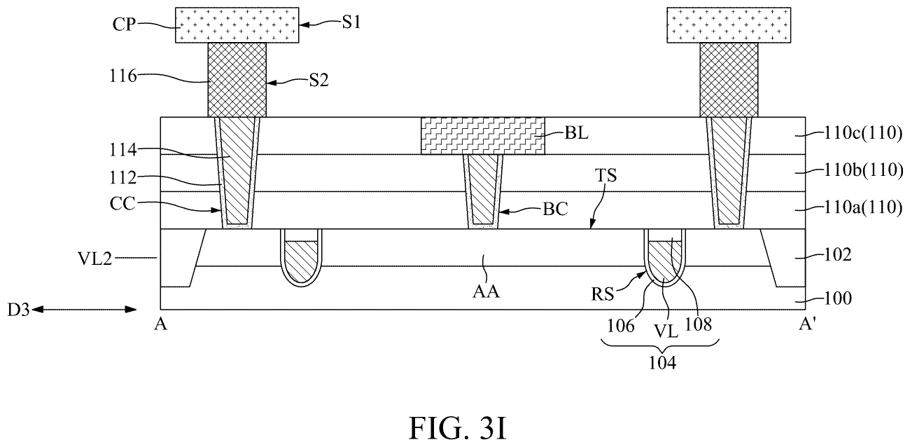

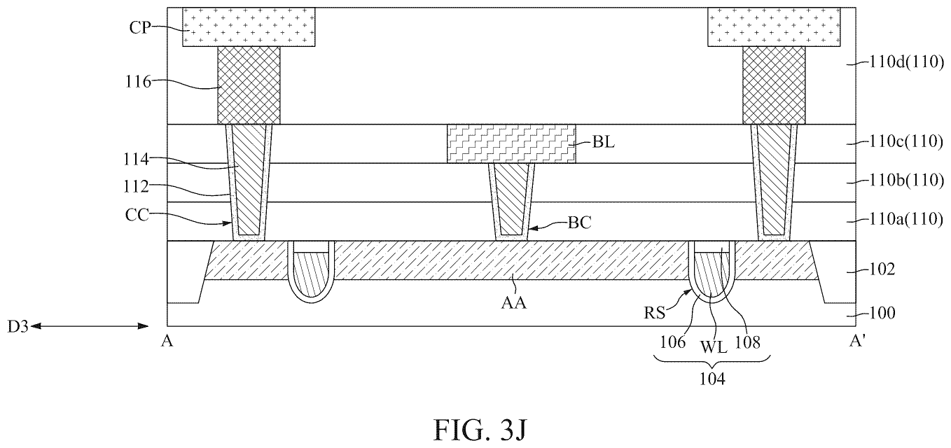

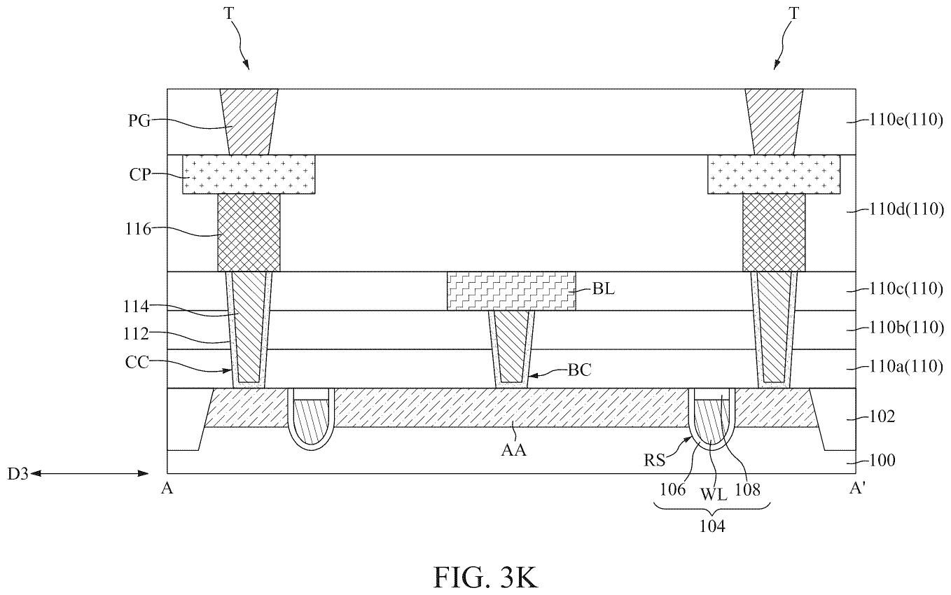

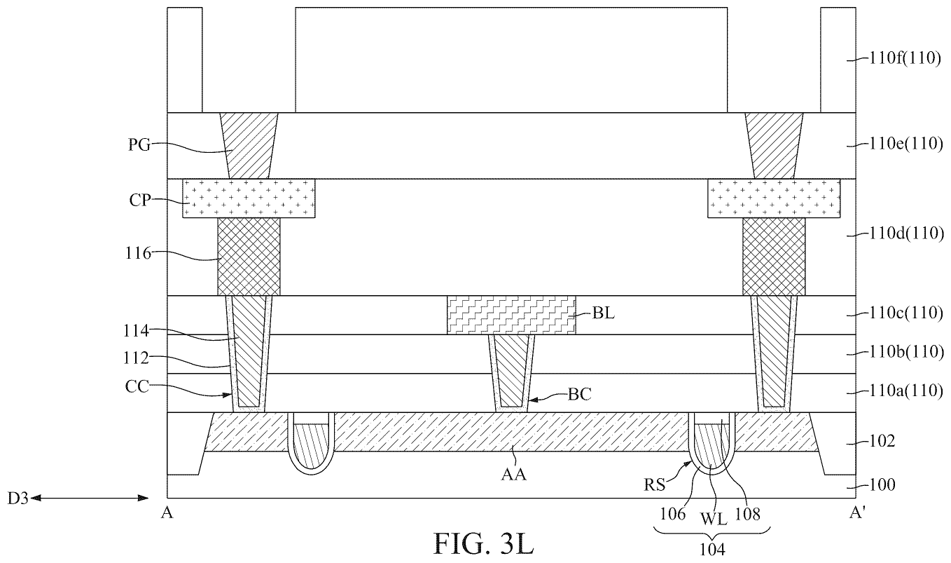

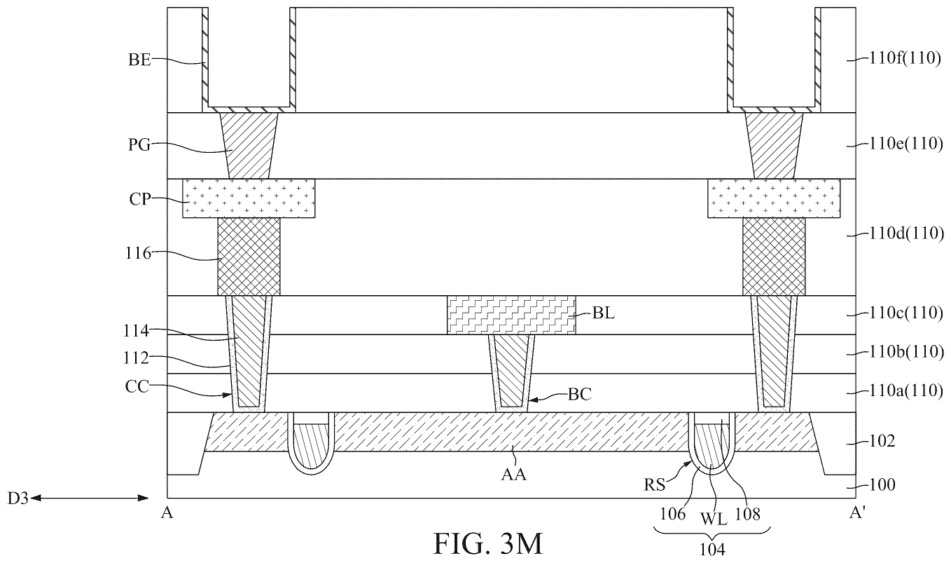

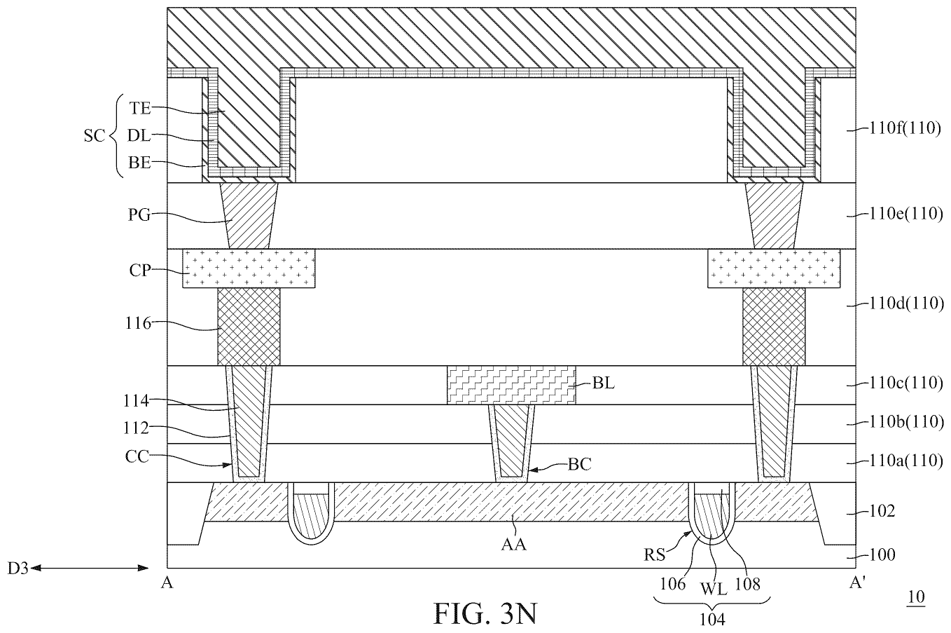

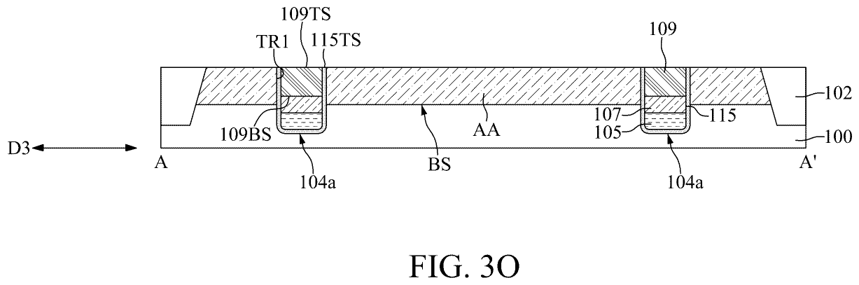

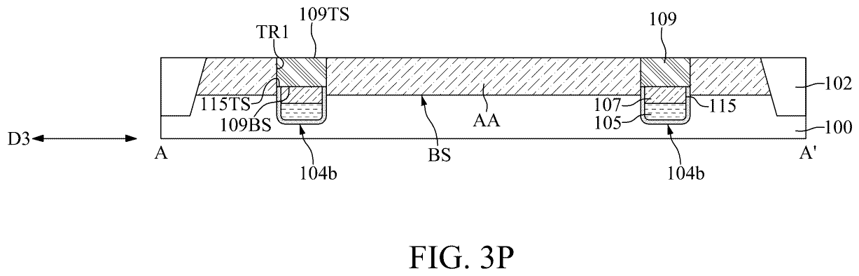

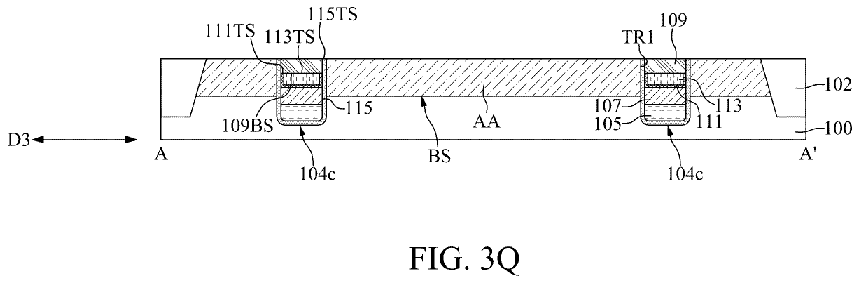

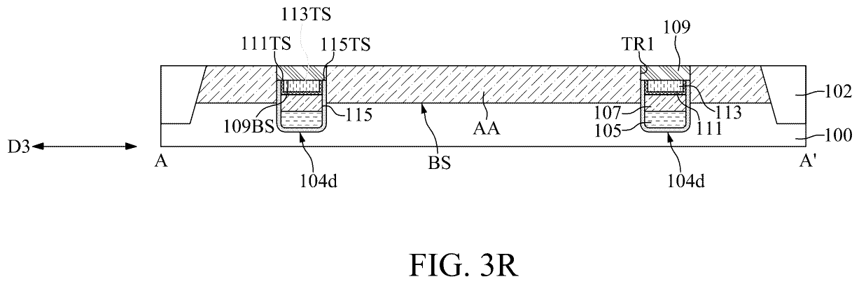

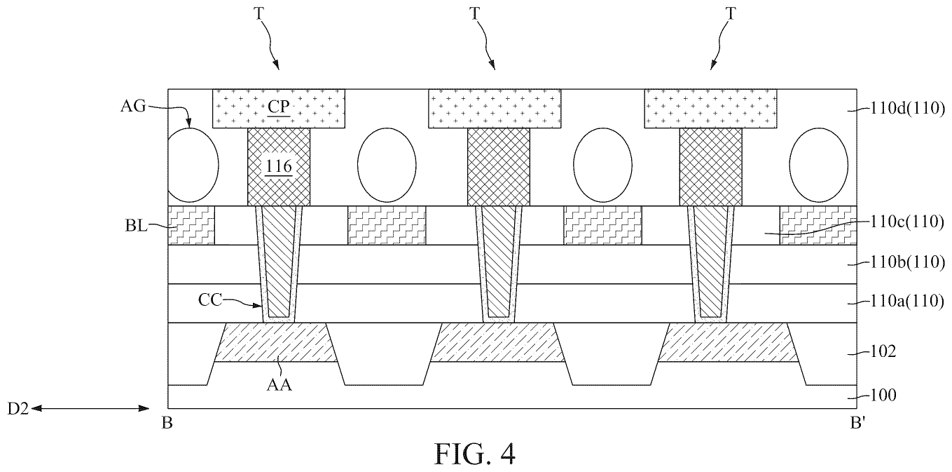

FIG. 2 is a flow diagram illustrating a manufacturing method of the semiconductor device 10 shown in FIGS. 1A to 1C. FIG. 3A to. 3N are schematic cross-sectional views along one of the active regions AA (e.g., along the line A-A′ shown in FIG. 1A) in the structures at various stages during the manufacturing of the semiconductor device 10. FIGS. 3O to 3R are schematic cross-sectional views of alternative intermediate structures in step S15 of the method in FIG. 2 in accordance with alternative embodiments of the present disclosure. FIG. 4 is another schematic cross-sectional view (along the line B-B′ shown in FIG. 1B) of the structure at the stage illustrated in FIG. 3J.

Referring to FIGS. 2 and 3A, step S11 is performed, wherein the isolation structure 102 is formed in the substrate 100. The isolation structure 102 defines portions of the substrate 100 to be formed as the active regions AA. In some embodiments, the isolation structure 102 is a trench isolation structure. In such embodiments, a method for forming the isolation structure 102 may include forming a trench at a surface of the substrate 100 by a lithography process and an etching process (e.g., an anisotropic etching process), and depositing an insulating material into the trench. Next, a planarization process may be performed to remove portions of the insulating material above the substrate 10. A remaining portion of the insulating material forms the isolation structure 102. For example, the planarization process described in the present disclosure may include a chemical mechanical polishing (CMP) process, an etching process, or a combination thereof.

Next, step S13 is performed, wherein the active regions AA are formed in the portions of the substrate 100 laterally surrounded by the isolation structure 102. In some embodiments, the active regions AA are formed by an ion implantation process, during which n-type or p-type dopants are implanted into the substrate 100. In such embodiments, the isolation structure 102 may function as a mask during the ion implantation process.

Referring to FIGS. 2 and 3B, step S15 is performed, wherein the recess gate structures 104 are formed in the substrate 100. As described with reference to FIGS. 1A and 1B, the recess gate structures 104 may be respectively formed in a line shape, wherein the line intersects the active regions AA. In addition, the recess gate structures 104 may respectively include the gate dielectric layer 106, the word line WL, and the insulating capping layer 108. In some embodiments, a method for forming the recess gate structures 104 may include forming the recesses RS at the surface of the substrate 100 using a lithography process and an etching process (e.g., an anisotropic etching process). Next, the gate dielectric layers 106 may be conformally formed in the recesses RS by an oxidation process or a deposition process (e.g., a chemical vapor deposition (CVD) process). A conductive material is subsequently deposited in the recesses RS by a deposition process (e.g., a CVD process or a physical vapor deposition (PVD) process), and is etched back to form the word lines WL. Next, an insulating material is deposited in the recesses RS by a deposition process (e.g., a CVD process), and portions of the insulating material above the substrate 100 may be removed by a planarization process, so as to form the insulating capping layers 108.

Referring to FIGS. 2 and 3C, step S17 is performed, wherein at least one dielectric layer 110 is formed on the substrate 100. For example, two dielectric layers 110 including a dielectric layer 110a and a dielectric layer 110b are formed on the substrate 100. In some embodiments, a method for forming the dielectric layers 110a and 110b includes a deposition process (e.g., a CVD process).

Referring to FIGS. 2 and 3D, step S19 is performed, wherein the bit line contacts BC are formed in the previously-formed dielectric layer(s) 110 (e.g., the dielectric layers 110a and 110b). In some embodiments, the bit line contacts BC may respectively include the conductive pillar 114 and the barrier layer 112. In such embodiments, a method for forming the bit line contacts BC may include forming via holes in the dielectric layer(s) 110 (e.g., the dielectric layers 110a and 110b) by a lithography process and an etching process (e.g., an anisotropic etching process). Subsequently, the barrier layers 112 are conformally formed in the via holes by a deposition process (e.g., a CVD process), and the conductive pillars 114 are further deposited in the via holes by another deposition process (e.g., a CVD process) or a plating process. For example, the plating process described in the present disclosure may include an electroplating process or an electro-less plating process. In addition, a planarization process may be performed to remove materials of the conductive pillars 114 and the barrier layers 112 outside the via holes.

Referring to FIGS. 2 and 3E, step S21 is performed, wherein the bit lines BL and an additional dielectric layer 110 (e.g., a dielectric layer 110c) are formed on the current structure. The dielectric layer 110c may be formed by a method same as methods of the dielectric layers 110a and 110b. In some embodiments, a method for forming the bit lines BL may include forming trenches in the dielectric layer 110c, and depositing a conductive material into the trenches by a deposition process (e.g., a PVD process), a plating process, or a combination thereof. In addition, a planarization process may be performed to remove portions of the conductive material above the dielectric layer 110c, and remaining portions of the conductive material form the bit lines BL.

Referring to FIGS. 2 and 3F, step S23 is performed, wherein the capacitor contacts CC are formed in the dielectric layers 110 (e.g., the dielectric layers 110a to 110c). In some embodiments, a method for forming the capacitor contacts CC is similar to the method for forming the bit line contacts BC, except that deeper via holes are formed for accommodating the capacitor contacts CC.

Referring to FIGS. 2 and 3G, step S25 is performed, wherein the first and second conductive layers 108 and 120 are globally formed on the current structure. In other words, the capacitor contacts CC, the bit lines BL and the current topmost dielectric layer 110 (e.g., the dielectric layer 110c) may be covered by the first and second conductive layers 118 and 120. The second conductive layer 120 is stacked on the first conductive layer 118. The conductive pillars 116 and the landing pads CP will be formed by patterning the first and second conductive layers 118 and 120 in subsequent steps. In some embodiments, the first conductive layer 118 has a thickness greater than a thickness of the second conductive layer 120. In addition, in some embodiments, a conductive material for forming the second conductive layer 120 has a resistivity lower than a resistivity of the conductive material for forming the first conductive layer 118, and the conductive material for forming the first conductive layer 118 has a sufficient etching selectivity with respect to the conductive material for forming the second conductive layer 120. A method for forming each of the first and second conductive layers 118 and 120 may include a deposition process (e.g., a PVD process), a plating process, or a combination thereof.

Referring to FIGS. 2 and 3H, step S27 is performed, wherein the first and second conductive layers 118 and 120 are patterned to form initial conductive pillars 116′ and the landing pads CP. During such patterning, portions of the first and second conductive layers 118 and 120 are removed, and the bit lines BL as well as portions of the current topmost dielectric layer 110c may be exposed. Sidewalls of the formed initial conductive pillars 116′ may be substantially coplanar with sidewalls of the formed landing pads CP. In other words, a footprint area of each initial conductive pillar 116′ may be substantially identical to a footprint area of the overlying landing pad CP. The conductive pillars 116 will be formed by laterally recessing the initial conductive pillars 116′ in the subsequent step. In some embodiments, a method for forming the initial conductive pillars 116′ and the landing pads CP may include a lithography process and a first etching process, wherein the first etching process may be a single etching process (e.g., a single anisotropic etching process) or may include two etching processes (e.g., two anisotropic etching processes). When the first etching process is a single etching process, the first and second conductive layers 118 and 120 are partially removed in the same etching process.

Referring to FIGS. 2 and 3I, step S29 is performed, wherein the initial conductive pillars 116′ are laterally recessed, so as to form the conductive pillars 116. In some embodiments, a method for laterally recessing the initial conductive pillars 116′ includes a second etching process, such as an isotropic etching process (e.g., a wet etching process). In the embodiments where the conductive material for forming the landing pads CP has a sufficient etching selectivity with respect to the conductive material for forming the initial conductive pillars 116′, damage to the landing pads CP may be avoided (or the landing pads CP may be only slightly consumed) during such isotropic etching process. As a result, the formed conductive pillars 116 can be laterally recessed with respect to the landing pads CP. In addition, in some embodiments, the conductive material for forming the bit lines BL also has an etching selectivity with respect to the conductive material for forming the initial conductive pillars 116′, and the bit lines BL may be undamaged (or only slightly consumed) during the isotropic etching process.

Referring to FIGS. 2, 3J and 4, step S31 is performed, wherein another dielectric layer 110 (e.g., the dielectric layer 110d) is formed. The conductive pillars 116 and the landing pads CP form stacking structures T on the capacitor contacts CC, and define recesses in between. The dielectric layer 110d is deposited in the recesses defined by the stacking structures T. In some embodiments, a method for forming the dielectric layer 110d includes a deposition process (e.g., a CVD process), and may further include a planarization process for removing excess material above the landing pads CP. As shown in FIGS. 3J and 4, in some embodiments, a width of the recess between adjacent stacking structures T arranged along a column direction (i.e., the direction D2) is much less than a width of the recess between adjacent stacking structures T arranged along an extending direction of the active regions AA (i.e., the direction D3). As shown in FIG. 4, the dielectric layer 110d may not fill the narrow recesses arranged along the column direction (i.e., the direction D2). Since the conductive pillars 116 are laterally recessed from the landing pads CP, a distance between adjacent landing pads CP is less than a distance between adjacent conductive pillars 116. In other words, the recesses defined between the stacking structures T respectively have a relatively narrow top portion and a relatively wide bottom portion. When the dielectric layer 110d is deposited in the narrow recesses (i.e., the recesses arranged along the direction D2), the relatively narrow top portions of such recesses may be sealed before the relatively wide bottom portions of the recesses can be filled. As a result, the air gaps AG may be formed in the relatively wide bottom portions. In other words, the possibly-formed air gaps AG are located between the conductive pillars 116 arranged along the column direction (i.e., the direction D2). As dimensions of the recesses, deposition conditions, and other parameters vary, the air gaps AG may be formed in different shapes, and top ends of the air gaps AG may or may not extend above top ends of the conductive pillars 116. In some embodiments, the air gaps AG may not expose sidewalls of the conductive pillars 116 or top surfaces of the bit lines BL. In alternative embodiments, some portions of the conductive pillars 116 and/or some portions of the bit lines BL may be exposed by the air gaps AG.

Referring to FIGS. 2 and 3K, step S33 is performed, wherein the capacitor plugs PG and another dielectric layer 110 (e.g., the dielectric layer 110e) are formed on the current structure. The dielectric layer 110e is located on the dielectric layer 110d and the landing pads CP, and the capacitor plugs PG penetrate through the dielectric layer 110e to establish an electrical connection with the landing pads CP. In some embodiments, a dielectric material layer may be globally formed on the dielectric layer 110d and the landing pads CP by a deposition process (e.g., a CVD process), and through holes are then formed in the dielectric material layer by a lithography process and an etching process (e.g., an anisotropic etching process), to form the dielectric layer 110e. Subsequently, a conductive material is deposited in the through holes by a deposition process (e.g., a PVD process), a plating process, or a combination thereof, and a planarization process may be performed to remove portions of the conductive material over the dielectric layer 110e. Remaining portions of the conductive material form the capacitor plugs PG.

Referring to FIGS. 2 and 3L, step S35 is performed, wherein one more dielectric layer 110 (e.g., the dielectric layer 110f) is formed on the current structure. The dielectric layer 110f is located on the dielectric layer 110e, and has openings overlapping the capacitor plugs PG. In some embodiments, such openings further overlap portions of the dielectric layer 110e surrounding the capacitor plugs PG. In some embodiments, a dielectric material layer may be globally formed on the dielectric layer 110e and on the capacitor plugs PG by a deposition process (e.g., a CVD process). Openings (as shown in FIG. 3L) are subsequently formed in the dielectric material layer by a lithography process and an etching process (e.g., an anisotropic etching process) to form the dielectric layer 110f.

Referring to FIGS. 2 and 3M, step S37 is performed, wherein the bottom electrodes BE are formed on the exposed capacitor plugs PG. The bottom electrodes BE are conformally formed in the openings of the dielectric layer 110f and are separated from one another. Accordingly, the bottom electrodes BE may cover the capacitor plugs PG and establish an electrical connection with the capacitor plugs PG. In embodiments where the openings of the dielectric layer 110f further overlap portions of the dielectric layer 110e surrounding the capacitor plugs PG, such portions of the dielectric layer 110e are covered by the bottom electrodes BE. In some embodiments, a conductive material layer is conformally formed to cover surfaces of the dielectric layer 110f as well as exposed surfaces of the capacitor plugs PG and the dielectric layer 110e. Next, a planarization process is performed to remove portions of the conductive material layer over the dielectric layer 110f. Remaining portions of the conductive material layer form the bottom electrodes BE.

Referring to FIGS. 2 and 3N, step S39 is performed, wherein the dielectric layer DL and the top electrode TE are sequentially formed on the current structure. The dielectric layer DL conformally covers exposed surfaces of the dielectric layer 110f and the bottom electrodes BE. The top electrode TE fills the openings of the dielectric layer 110f and covers a top surface of the dielectric layer DL. In some embodiments, the dielectric layer DL and the top electrode TE are globally formed. In such embodiments, the storage capacitors SC share the same dielectric layer DL and the same top electrode TE, but include separate bottom electrodes BE. A method for forming the dielectric layer DL may include a deposition process (e.g., a CVD process), while a method for forming the top electrode TE may include a deposition process (e.g., a PVD process), a plating process, or a combination thereof.

As described above, the semiconductor device 10 has been formed using a manufacturing method in accordance with some embodiments of the present disclosure. Additionally, the semiconductor device 10 may undergo further manufacturing and/or testing processes.

Referring to FIG. 2 and FIGS. 3O to 3R, in accordance with alternative embodiments, step S15 is performed, wherein the recess gate structures 104a, 104b, 104c and 104d are respectively formed. After the subsequent steps described above (i.e., steps S17 to S39 in FIG. 2) are sequentially performed, the semiconductors 10a, 10b, 10c and 10c as shown in FIGS. 1D, 1E, 1F and 1G may be obtained.

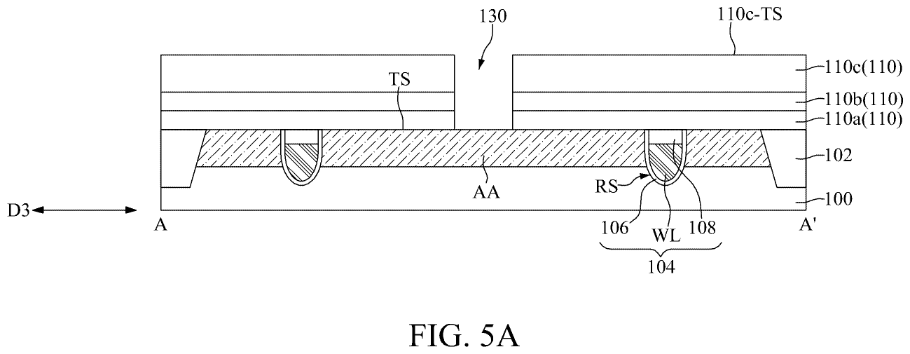

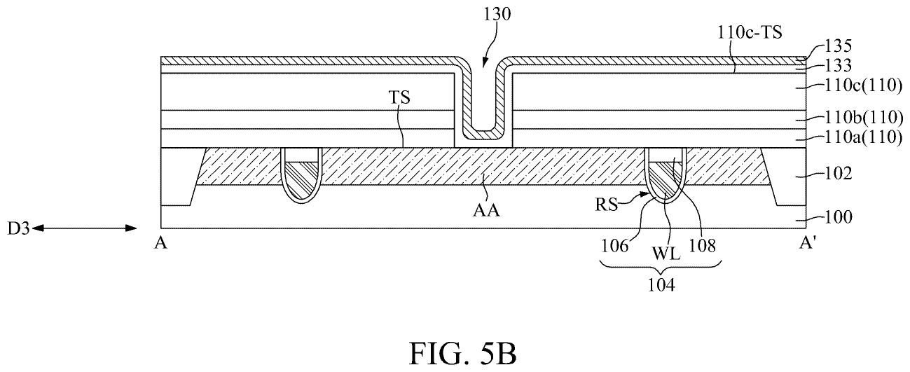

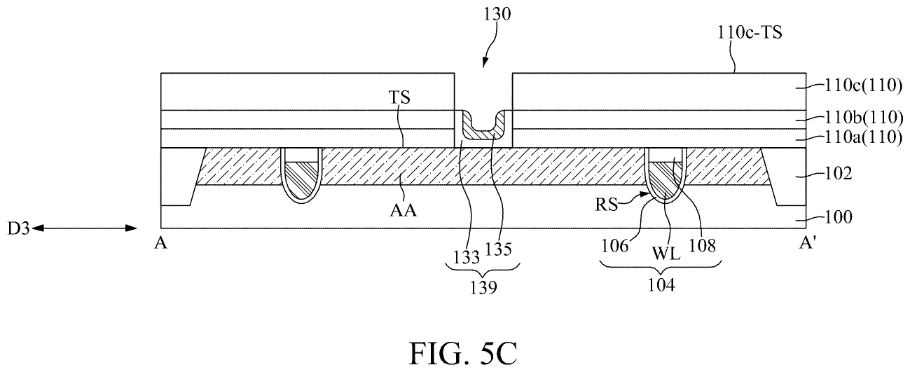

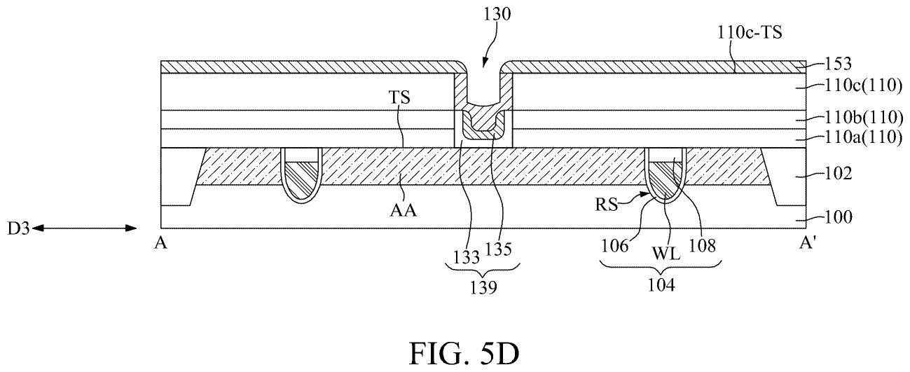

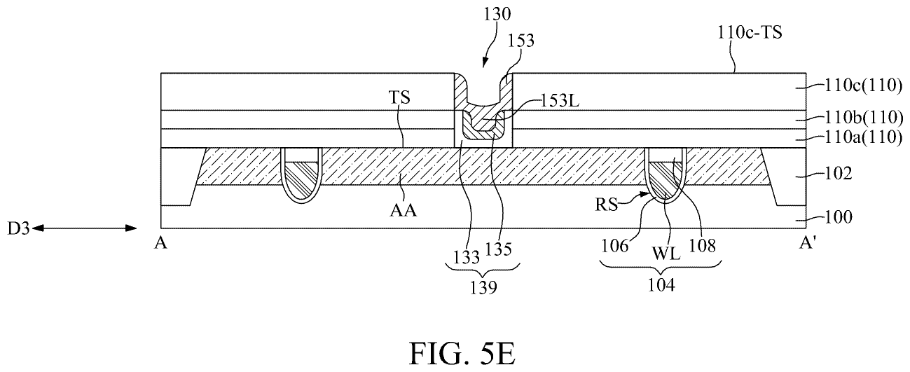

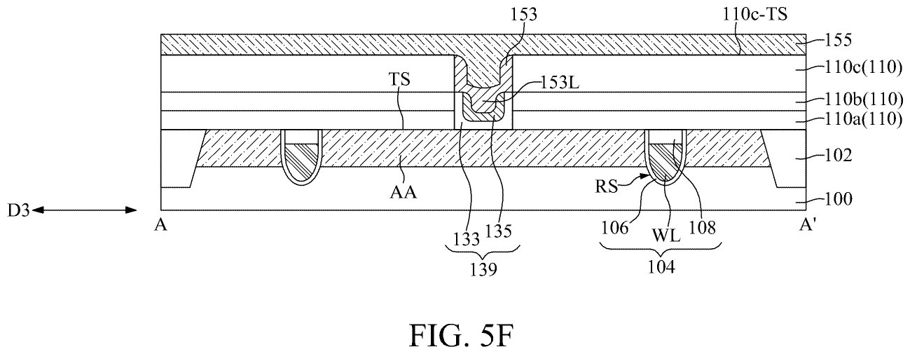

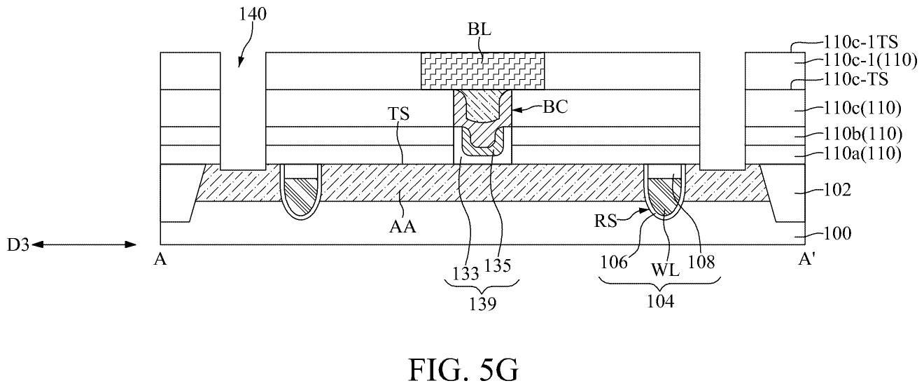

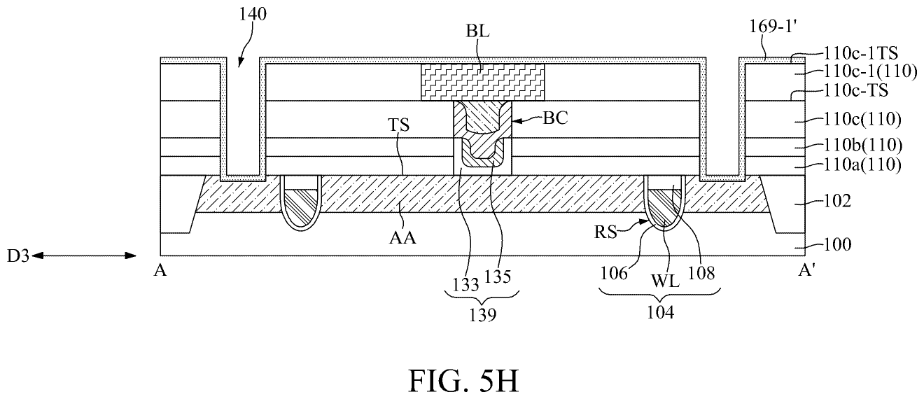

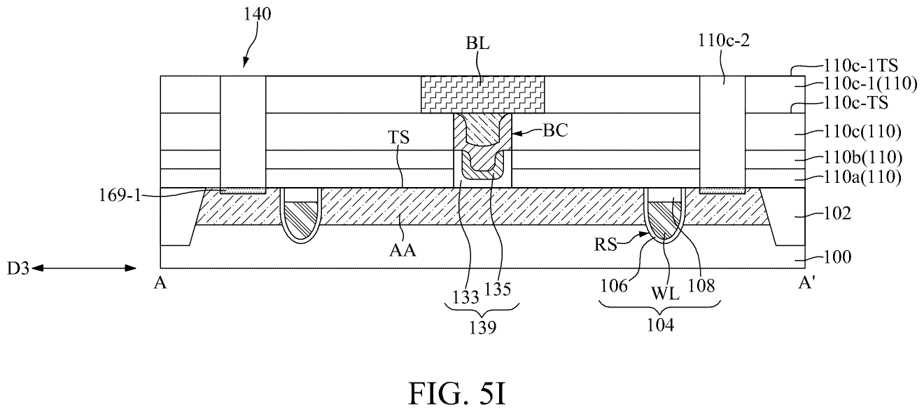

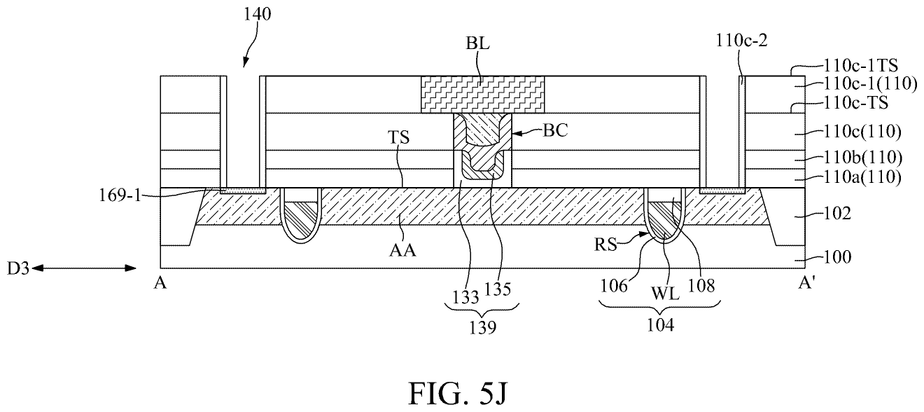

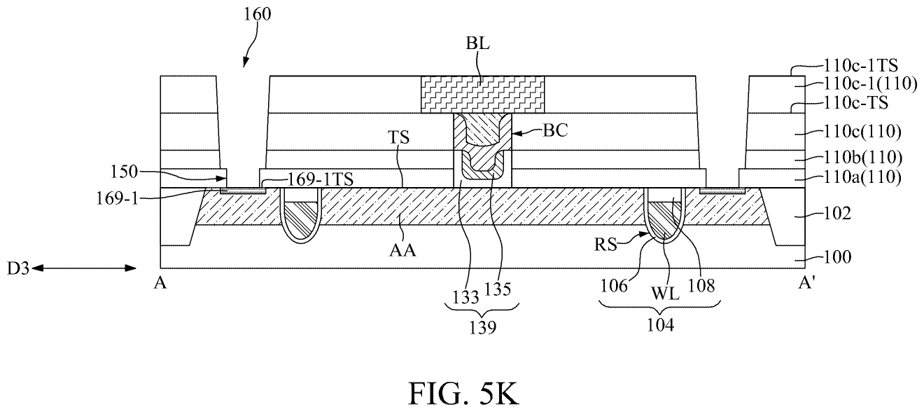

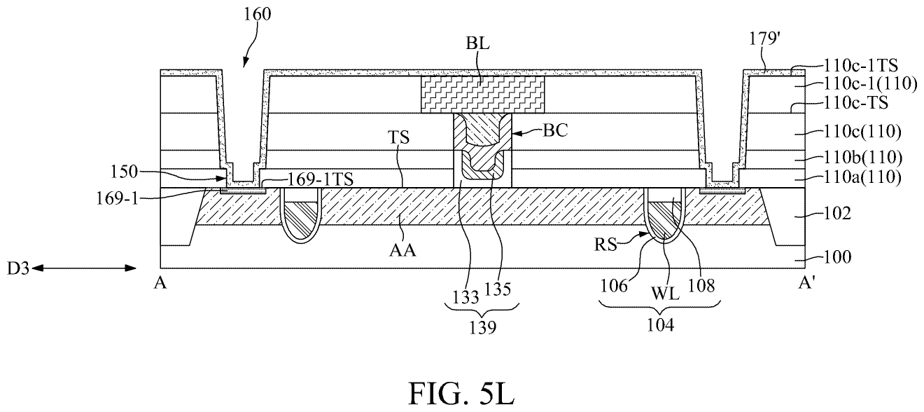

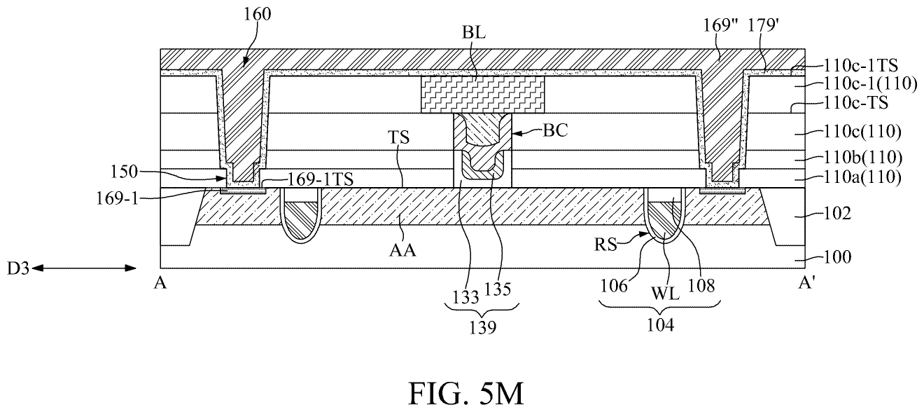

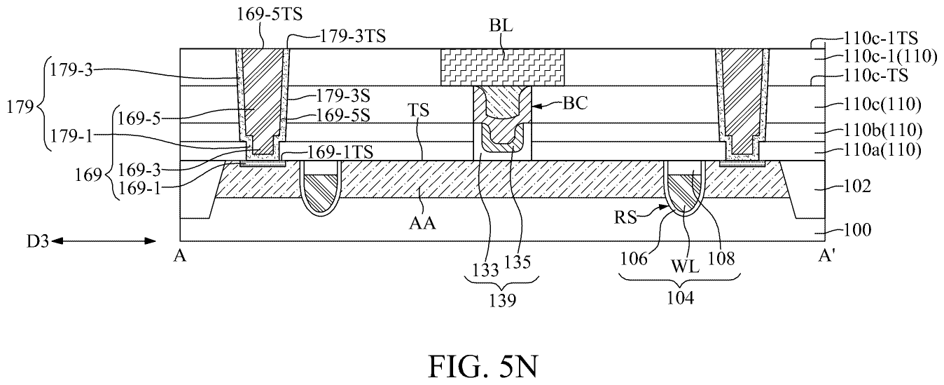

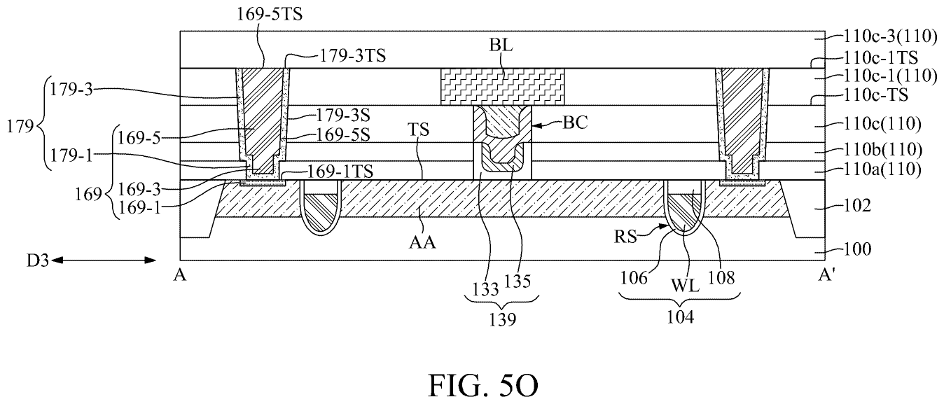

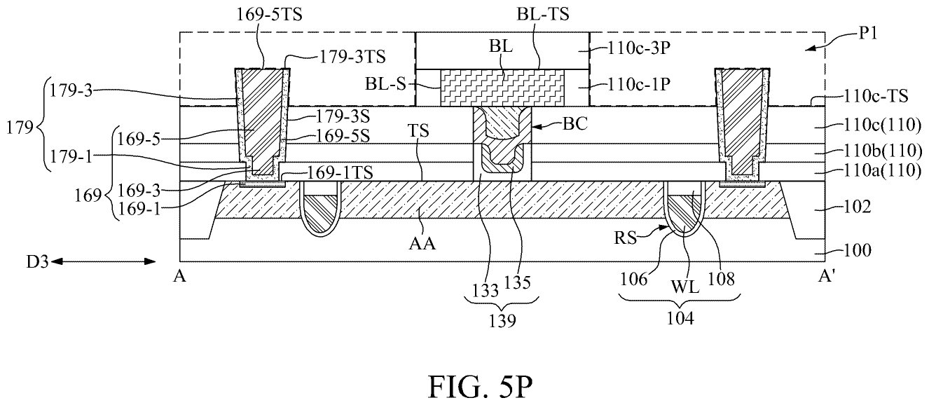

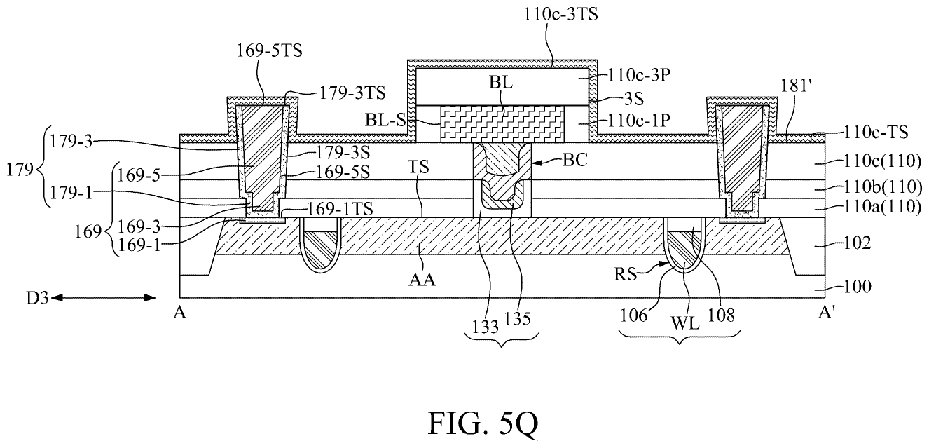

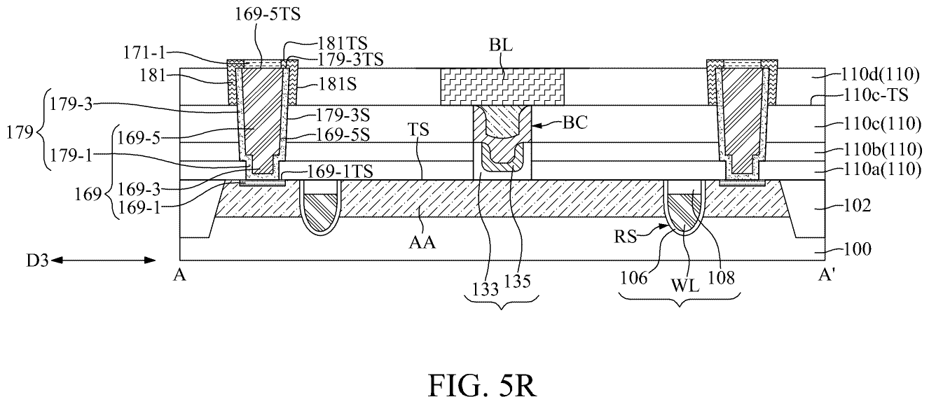

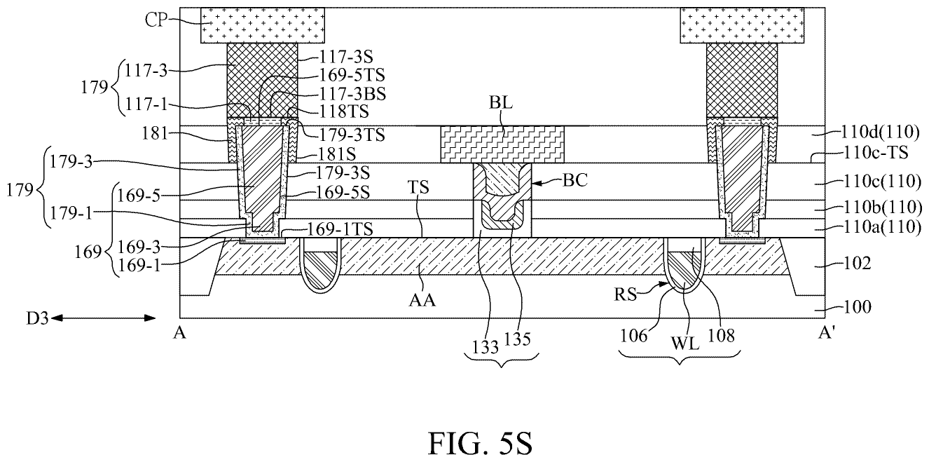

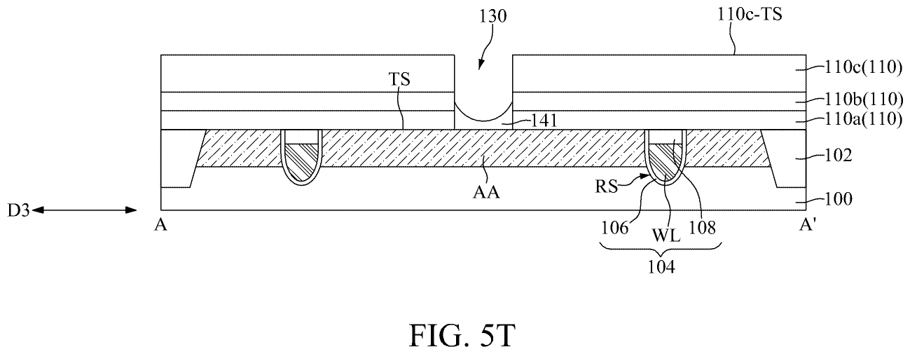

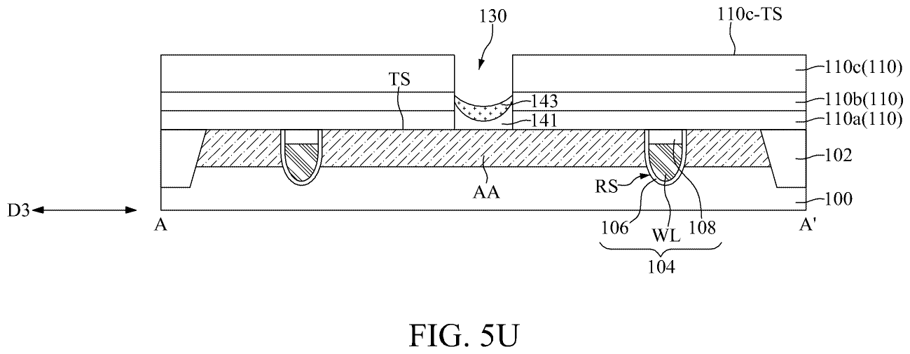

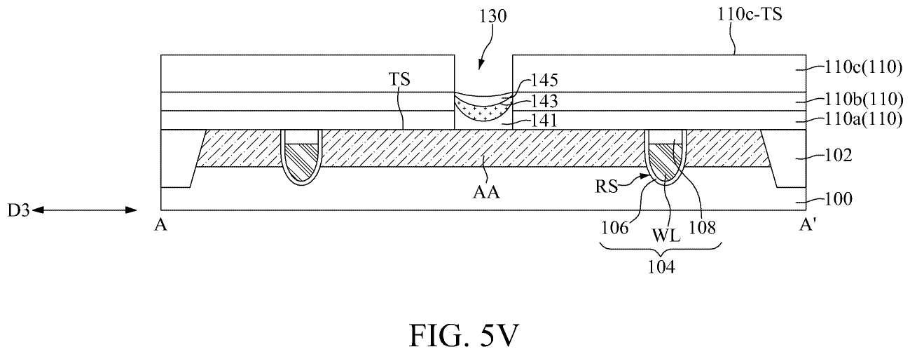

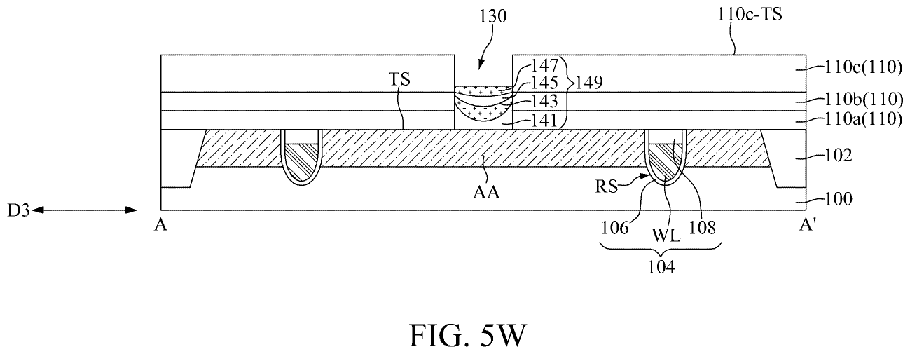

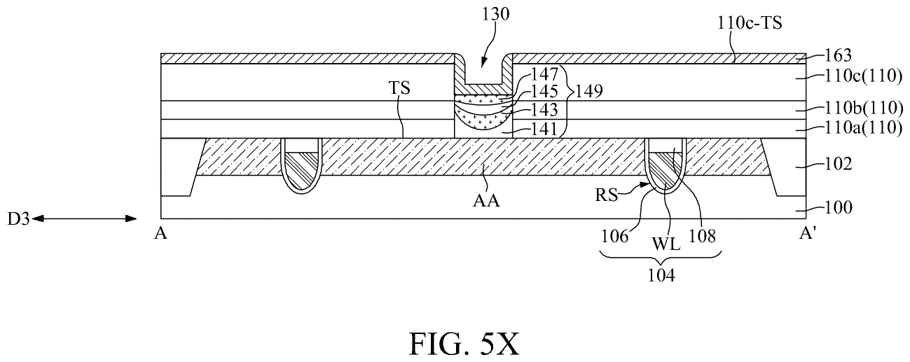

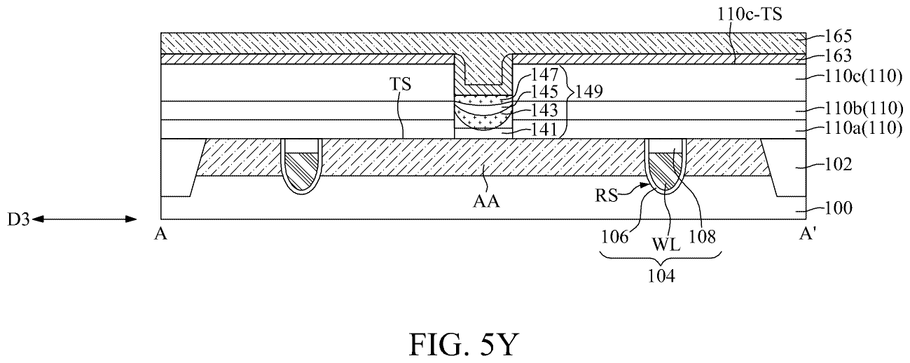

FIGS. 5A to 5F are schematic cross-sectional views of alternative intermediate structures in step S19 of the method in FIG. 2 in accordance with alternative embodiments of the present disclosure. Specifically, in step S19, a bit line contact BC including a polysilicon stack 139 disposed over the active region AA and a contact structure 159 disposed directly over the polysilicon stack 139, as shown in FIG. 1I, are formed. Formation of the bit line contact BC is described below.

Referring to FIGS. 2 and 5A, an intermediate structure, as shown in FIG. 3C, may be provided, and an opening 130 may be formed penetrating through the dielectric layer(s) (e.g., the dielectric layers 110a, 110b, and 110c). It should be noted that the intermediate structure includes three dielectric layers (e.g., the dielectric layers 110a, 110b, and 110c). The opening 130 may be formed by an etching process, and location of the opening 130 may be defined by a patterned mask formed over the dielectric layer 110c. The etching process may include a dry etching process, a wet etching process, or a combination thereof. After the etching process, the patterned mask may be removed.

Referring to FIGS. 2 and 5B, a first polysilicon layer 133 and a second polysilicon layer 135 are sequentially formed in the opening 130 and over a top surface 110c-TS of the dielectric layer 110c. In some embodiments, the first polysilicon layer 133 and the second polysilicon layer 135 are formed using a deposition process, such as a CVD process, a PVD process, an ALD process, or a combination thereof.

In some embodiments, the first polysilicon layer 133 is undoped, and the second polysilicon layer 135 is doped with arsenic (As), boron (B), or phosphorous (P). In some embodiments, the second polysilicon layer 135 is in-situ doped during the deposition process. In some embodiments, the second polysilicon layer 135 is not in-situ doped, and instead an implantation process is performed to dope the second polysilicon layer 135.

Referring to FIGS. 2 and 5C, an etch-back process is performed on the first polysilicon layer 133 and the second polysilicon layer 135 to remove portions of the first polysilicon layer 133 and the second polysilicon layer 135 over the top surface 110c-TS of the dielectric layer 110c, and to remove portions of the first polysilicon layer 133 and the second polysilicon layer 135 occupying the upper portion of the opening 130. As a result, remaining portions of the first polysilicon layer 133 and the second polysilicon layer 135 together form a polysilicon stack 139. In some embodiments, the etch-back process may include a dry etching process, a wet etching process, or a combination thereof. In some embodiments, prior to the deposition of the second polysilicon layer 135, an etch-back process may be performed on the first polysilicon layer 133.

Referring to FIGS. 2 and 5D, a barrier layer 153 is formed within the opening 130, over the polysilicon stack 139, and on the top surface 110c-TS of the dielectric layer 110c. In some embodiments, the barrier layer 153 includes titanium (Ti), titanium nitride (TiN), or a combination thereof. Moreover, the barrier layer 153 may be formed using a deposition process, such as a CVD process, a PVD process, an ALD process, or a combination thereof.

Referring to FIGS. 2 and 5E, an etching process is performed on the barrier layer 153 to remove an excess portion of the barrier layer 153 over the top surface 110c-TS of the dielectric layer 110c. The excess portion of the barrier layer 153 may be removed by an etch-back process, or a planarization process (e.g., CMP, grinding, or the like). In some embodiments, a lower portion 153L of the barrier layer 153 is surrounded by the second polysilicon layer 135. In some embodiments, the barrier layer 153 is in direct contact with the first polysilicon layer 133 and the second polysilicon layer 135.

Referring to FIGS. 2 and 5F, the remaining portion of the opening 130 is filled by a conductive layer 155, and the conductive layer 155 extends over the top surface 110c-TS of the dielectric layer 110c. In some embodiments, the conductive layer 155 includes tungsten (W). Moreover, the conductive layer 155 may be formed by a deposition process, such as a CVD process, a PVD process, an ALD process, or a combination thereof.

Subsequently, a planarization process may be performed on the conductive layer 155 to remove an excess portion of the conductive layer 155 over the top surface 110c-TS of the dielectric layer 110c. After the planarization process, a conductive structure 159, which includes the barrier layer 153 and the conductive layer 155, is formed over the polysilicon stack 139 and surrounded by the dielectric layer 110c. Accordingly, as shown in FIG. 1I, a bit line contact BC is formed.

FIGS. 5G to 5S are schematic cross-sectional views of alternative intermediate structures in step S23 of the method in FIG. 2 in accordance with alternative embodiments of the present disclosure. Specifically, in step S23, a capacitor contact CC including a contact structure 169, a barrier layer 179, and a barrier spacer 181 is formed. Formation of the capacitor contact CC is described below.

Referring to FIGS. 2 and 5G, an intermediate structure may be provided, and an opening 140 may be formed penetrating through the dielectric layer(s) (e.g., the dielectric layers 110a, 110b, and 110c, and 110c-1) and into the substrate 100. It should be noted that the intermediate structure may be a semiconductor structure after the processes shown in FIGS. 5A to 5F and after step S21 in FIG. 2. The opening 140 may be formed by an etching process, and location of the opening 140 may be defined by a patterned mask formed over the bit line BL and the dielectric layer 110c-1 (e.g., the additional dielectric layer formed in step S21). The etching process may include a dry etching process, a wet etching process, or a combination thereof. After the etching process, the patterned mask may be removed.

Referring to FIGS. 2 and 5H, a contact material 169-1′ may be conformally deposited in the opening 140 and over the bit line BL and the dielectric layer 110c-1. In some embodiments, the deposition of the contact material 169-1′ includes CVD process, PVD process, ALD process, or a combination thereof. In some embodiments, the contact material 169-1′ may include a conductive material, such as tungsten, cobalt, zirconium, tantalum, titanium, aluminum, ruthenium, copper, metal carbide (e.g., tantalum carbide, titanium carbide, tantalum magnesium carbide), metal nitride (e.g., titanium nitride), transition metal aluminide, or a combination thereof.

Referring to FIGS. 2 and 5I, a removal process, such as a dry etching process, may be performed to eliminate portions of the contact material 169-1′, leaving only the portion below the top surface TS of the substrate 100 in place. Accordingly, a lower portion 169-1 of the contact structure 169 is formed. After the formation of the lower portion 169-1, a dielectric layer 110c-2 is deposited to overfill the remaining portion of the opening 140. In some embodiments, in order to achieve a better filling effect at the bottom of the opening 140, a material of the dielectric layer 110c-2 may be same as the material of the dielectric layer 110a. Subsequently, a planarization process may be performed to remove a portion of the dielectric layer 110c-2 over the top surface 110c-1TS of the dielectric layer 110c, providing a substantially flat surface for subsequent processing steps.

Referring to FIGS. 2 and 5J, an opening 150 may be formed penetrating through the dielectric layer 110-c2. From a cross-sectional perspective, a width of the opening 150 is less than a width of the opening 140, and a center line of the opening 150 is substantially aligned with a center line of the opening 140. The opening 150 may be formed by an etching process, and location of the opening 150 may be defined by a patterned mask formed over the bit line BL and the dielectric layer 110c-1. The etching process may include a dry etching process, a wet etching process, or a combination thereof. After the etching process, the patterned mask may be removed. It should be noted that, after the formation of the opening 150, portions of the 110c-2 may be residual on sidewalls of the opening 140.

Referring to FIGS. 2 and 5K, an opening 160 may be formed by removing portions of the residual dielectric layer 110-c2 and portions of the dielectric layers 110c-1, 110c, and 110b. In other words, the residual portions of the dielectric layer 110-c2 in the dielectric layers 110c-1, 110c, and 110b may be removed, leaving only the residual portion in the dielectric layer 110-a. In addition, as mentioned above, the material of the dielectric layer 110-c2 and the material of the dielectric layer 110-a may be the same, resulting in no distinct boundary between the dielectric layer 110-c2 and the dielectric layer 110-a.

As shown in FIG. 5K, the opening 160 may be positioned over the opening 150. A center line of the opening 160 is substantially aligned with the center line of the opening 150. In some embodiments, the opening 160 may have a tapered profile. A width of the opening 160 gradually decreases at positions of increasing distance from the top surface 110c-TS of the dielectric layer 110c-1. In some embodiments, a minimum width of the opening 160 is substantially equal to the width W4 (shown in FIG. 1I) of the lower portion 169-1 of the contact structure 169. In some embodiments, the opening 160 may be formed by an etching process, and location of the opening 160 may be defined by a patterned mask formed over the bit line BL and the dielectric layer 110c-1. The etching process may include a dry etching process, a wet etching process, or a combination thereof. After the etching process, the patterned mask may be removed.

Referring to FIGS. 2 and 5L, a barrier material 179′ may be conformally deposited in the openings 150 and 160 and on the dielectric layer 110c-1 and the bit line BC. The barrier material may be, for example, titanium, titanium nitride, platinum, nickel, or a combination thereof. In some embodiments, the deposition of the barrier material 179′ includes CVD process, PVD process, ALD process, or a combination thereof.

Referring to FIGS. 2 and 5M, a conductive material 169″, such as tungsten, cobalt, zirconium, tantalum, titanium, aluminum, ruthenium, copper, metal carbides, metal nitride, transition metal aluminide, or a combination thereof, may be deposited on the barrier material 179′ and in the openings 150 and 160. In some embodiments, the deposition of the conductive material 169″ includes CVD process, PVD process, ALD process, or a combination thereof.

Referring to FIGS. 2 and 5N, after the deposition process is performed, a planarization process, such as a chemical mechanical polishing, may be performed on the conductive material 169″ and the barrier material 179′until the top surface 110c-1TS of the dielectric layer 110c-1 is exposed to remove excess materials, provide a substantially flat surface for subsequent processing steps, and concurrently form a middle portion 169-3 and an upper portion 169-5 of the contact structure 169, and a lower portion 179-1 and an upper portion 179-3 of the barrier layer 179.

Referring to FIGS. 2 and 5O, a dielectric layer 110c-3 may be deposited over the dielectric layer 110c-1, the bit line BL, the upper portion 169-5 of the contact structure 169, and the upper portion 179-3 of the barrier layer 179 using a deposition process. In some embodiments, the dielectric layer 110c-3 may include silicon nitride, silicon oxide, silicon oxynitride, undoped silica glass, borosilica glass, phosphosilica glass, borophosphosilica glass, or a combination thereof. In some embodiments, the deposition of the dielectric layer 110c-3 includes CVD process, PVD process, ALD process, or a combination thereof.

Referring to FIGS. 2 and 5P, as depicted by the dashed line, a portion P1 of the dielectric layers 110c-1 and 110c-3 may be removed, leaving only portion 110c-1P of the dielectric layer 110c-1 on sidewall BL-S and portion 110c-3P of the dielectric layer 110c-3 over the bit line BL. The removal of the portion P1 of the dielectric layers 110c-1 and 110c-3 may be performed using an etching process, such as a dry etching process, a wet etching process, or a combination thereof.

Referring to FIGS. 2 and 5Q, a layer of barrier spacer material 181′ may be conformally deposited to cover the top surface 110c-TS of the dielectric layer 110c, a top surface 169-5TS of the upper portion 169-5 of the contact structure 169, a top surface 179-3TS and a sidewall 179-3S of the upper portion 179-3 of the barrier layer 179, a top surface 110c-3TS of the portion 110c-3P of the dielectrics 110c-3, and a sidewall S3 of the portion 110c-3P and the portion 110c-1P. In some embodiments, the barrier spacer material 181′ may be, for example, silicon or germanium. In some embodiments, the deposition of the dielectric layer 110c-3 includes CVD process, PVD process, ALD process, or a combination thereof.

Referring to FIGS. 2 and 5R, a thermal treatment may be performed. During the thermal treatment, metal atoms from the upper portion 169-5 of the contact structure 169 and upper portion 179-3 of the barrier layer 179 may react chemically with silicon atoms from the layer of barrier spacer material 181′ to form a lower portion 117-1 of the conductive pillar 117 on the upper portion 169-5 of the contact structure 169, and to form the barrier spacers 181 on sidewalls 179-3S and top surfaces 179-3TS of barrier layers 179. In some embodiments, a top surface of the lower portion 117-1 of the conductive pillar 117 is lower than a top surface of the barrier spacer 181. In some embodiments, the top surface of the lower portion 117-1 of the conductive pillar 117 is substantially coplanar with the top surface of the barrier spacer 181.

The lower portion 117-1 of the conductive pillar 117 and the barrier spacers 181 may include titanium silicide, nickel silicide, nickel platinum silicide, tantalum silicide, or cobalt silicide. The thermal treatment may be a dynamic surface annealing process. After the thermal treatment, a cleaning process may be performed to remove the unreacted barrier spacer material 181′. The cleaning process may be, for example, a wet etch using potassium hydroxide.

Referring to FIGS. 2 and 5S, an upper portion 117-3 of conductive pillar 117 may be formed on the lower portion 117-1 and the barrier spacers 181, and a landing pad CP may be formed on the upper portion 117-3 of conductive pillar 117. In some embodiments, a bottom surface 117-3BS is substantially coplanar with a top surface 181TS of the barrier spacer 181. A sidewall 117-3S of the conductive pillar 117 is substantially coplanar with a sidewall 181S of the barrier spacer 181. In some embodiments, a width of the upper portion 117-3 is greater than a width of the lower portion 117-1. Materials and processes of the upper portion 117-3 and the landing pad CP are same as or similar to those of the conductive pillar 116 and landing pad CP illustrated in FIGS. 3G to 3I, and repeated descriptions are omitted. Subsequently, followed by processes illustrated in FIGS. 3J to 3N, the semiconductor device 10f as shown in FIG. 1I is obtained.

FIGS. 5T to 5Y are schematic cross-sectional views of alternative intermediate structures in step S19 of the method in FIG. 2 in accordance with alternative embodiments of the present disclosure. Specifically, in step S19, a bit line contact BC including a polysilicon stack 149 disposed over the active region AA and a contact structure 167 disposed directly over the polysilicon stack 149, as shown in FIG. 1J, is formed. Formation of the bit line contact BC is described below.

Referring to FIGS. 2 and 5T, an intermediate structure as shown in FIG. 5A may be provided, and a first polysilicon layer 141 is formed in the opening 130. In some embodiments, the first polysilicon layer 141 is undoped, and is formed by a deposition process, such as a CVD process, a PVD process, an ALD process, or a combination thereof. After the deposition process, an etch-back process may be performed to remove excess portion(s) of the first polysilicon layer 141 in an upper portion of the opening 130 and/or over the top surface of the dielectric layer 110c.

Referring to FIGS. 2 and 5U, a second polysilicon layer 143 is formed in the opening 130 and over the first polysilicon layer 141. In some embodiments, the second polysilicon layer 143 is formed using a deposition process, such as a CVD process, a PVD process, an ALD process, or a combination thereof. In some embodiments, the second polysilicon layer 143 is doped with arsenic (As), boron (B), or phosphorous (P), and the second polysilicon layer 143 is in-situ doped during the deposition process. In some embodiments, the second polysilicon layer 143 is not in-situ doped, and instead an implantation process is performed to dope the second polysilicon layer 143. After the deposition process, an etch-back process may be performed to remove excess portion(s) of the second polysilicon layer 143 in the upper portion of the opening 130 and/or over the top surface of the dielectric layer 113.

Referring to FIGS. 2 and 5V, a third polysilicon layer 145 is formed in the opening 130 and over the second polysilicon layer 143. In some embodiments, the third polysilicon layer 145 is undoped, and is formed by a deposition process, such as a CVD process, a PVD process, an ALD process, or a combination thereof. After the deposition process, an etch-back process may be performed to remove excess portion(s) of the third polysilicon layer 145 in the upper portion of the opening 130 and/or over the top surface of the dielectric layer 113.

Referring to FIGS. 2 and 5W, a fourth polysilicon layer 147 is formed in the opening 130 and over the third polysilicon layer 145. In some embodiments, the fourth polysilicon layer 147 is formed using a deposition process, such as a CVD process, a PVD process, an ALD process, or a combination thereof. In some embodiments, the fourth polysilicon layer 147 is doped with arsenic (As), boron (B), or phosphorous (P), and the dopant concentration of the second polysilicon layer 143 is greater than the dopant concentration of the fourth polysilicon layer 147.

In some embodiments, the fourth polysilicon layer 147 is in-situ doped during the deposition process. In some embodiments, the fourth polysilicon layer 147 is not in-situ doped, and instead an implantation process is performed to dope the fourth polysilicon layer 147. After the deposition process, an etch-back process may be performed to remove excess portion(s) of fourth polysilicon layer 147 in the upper portion of the opening 130 and/or over the top surface of the dielectric layer 113. After the etch-back process is performed, as illustrated, the remaining portions of the fourth polysilicon layer 147, the third polysilicon layer 145, the second polysilicon layer 143 and the first polysilicon layer 141 form a polysilicon stack 149 occupying the lower portion of the opening 130, in accordance with some embodiments. In some embodiments, the polysilicon stack 149 has a substantially flat top surface.

It should be noted that the polysilicon stack 149 may have more than four polysilicon layers. In some embodiments, the processes for forming the third polysilicon layer 145 and the fourth polysilicon layer 147 are repeated as a cycle to form more polysilicon layers over the fourth polysilicon layer 147. For example, a fifth polysilicon layer, which is undoped, is formed over the fourth polysilicon layer 147, and a sixth polysilicon layer, which is doped with arsenic (As), boron (B), or phosphorous (P), is formed over the fifth polysilicon layer. In these cases, the dopant concentration of the fourth polysilicon layer 147 is greater than the dopant concentration of the sixth polysilicon layer, and the topmost polysilicon layer has a substantially flat top surface.

Referring to FIGS. 2 and 5X, a barrier layer 163 is formed in the opening 130 and over the polysilicon stack 149, and the barrier layer 163 extends over the top surface of the dielectric layer 113. In some embodiments, the barrier layer 163 includes titanium (Ti), titanium nitride (TiN), or a combination thereof. Moreover, the barrier layer 163 may be formed using a deposition process, such as a CVD process, a PVD process, an ALD process, or a combination thereof.

Referring to FIGS. 2 and 5Y, a conductive layer 165 is formed over the barrier layer 163, and the remaining portion of the opening 130 over the barrier layer 163 is filled by the conductive layer 165. In some embodiments, the conductive layer 135 includes tungsten (W). Moreover, the conductive layer 155 may be formed by a deposition process, such as a CVD process, a PVD process, an ALD process, or a combination thereof.

Next, a planarization process may be performed to remove the excess portions of the barrier layer 163 and the conductive layer 165 over the top surface of the stack of dielectric layers 110 (e.g., the top surface 110c-TS of dielectric layer 110c). After the planarization process, a conductive structure 169 including the barrier layer 163 and the conductive layer 165, as shown in FIG. 1J, is formed over the polysilicon stack 149 and surrounded by the dielectric layer 110.

The planarization process may include a CMP process, a grinding process, an etch-back process, or the like. In some embodiments, after the planarization process, as shown in FIG. 1J, the top surface 110cTS of the dielectric layer 110c is substantially coplanar with the top surface 163T of the barrier layer 163 and the top surface 165T of the conductive layer 165.

Additionally, followed by processes illustrated in FIGS. 5G to 5S and FIGS. 3J to 3N, the semiconductor device 10g as shown in FIG. 1J is obtained.

As described above, the semiconductor device according to embodiments of the present disclosure includes memory cells arranged as an array. Each memory cell includes a transistor and storage capacitor connected to the transistor. A conductive pillar and a landing pad are disposed between one of the storage capacitors and an active region of the transistor connected to this storage capacitor. The landing pad is disposed on the conductive pillar, and a sidewall of the conductive pillar is recessed from a sidewall of the landing pad. Therefore, a distance between the landing pads of adjacent memory cells is less than a distance between the conductive pillars of adjacent memory cells. As a result, while depositing a dielectric material between stacking structures (each of which includes one of the conductive pillars and the overlying landing pad), the space between adjacent landing pads may be sealed before the space between adjacent conductive pillars is filled. As a result, air gaps may be formed between the conductive pillars. Due to a low dielectric constant of the air sealed in the air gaps, a parasitic capacitance between the conductive pillars can be reduced by the formation of the air gaps, thus effectively reducing an RC delay of the semiconductor device. As a result, an operation speed of the semiconductor device can be improved. In embodiments where a resistivity of the landing pads is less than a resistivity of the conductive pillars, the parasitic capacitance between the landing pads may be limited, even though the space between the landing pads is narrower than the space between the conductive pillars.

One aspect of the present disclosure provides a semiconductor device including a substrate having an active region; a recess gate structure disposed in the substrate and intersecting the active region; a bit line contact comprising a polysilicon stack and disposed on the substrate; a conductive pillar disposed over the substrate and electrically connected to the active region; a landing pad disposed on the conductive pillar and electrically connected to the conductive pillar; and a stack of dielectric layers disposed over the substrate and laterally surrounding the bit line contact. The polysilicon stack comprises a first polysilicon layer and a second polysilicon layer disposed over the first polysilicon layer. The second polysilicon layer is in direct contact with the stack of dielectric layers.

Another aspect of the present disclosure provides a semiconductor device including a substrate having an active region; a stack of dielectric layers disposed over the substrate, wherein the stack of dielectric layers comprises a first dielectric layer, a second dielectric layer disposed over the first dielectric layer, a third dielectric layer disposed over the second dielectric layer, and a fourth dielectric layer disposed over the third dielectric layer; a recess gate structure disposed in the substrate and intersecting the active region; a bit line contact disposed on the substrate and laterally surrounded by the stack of dielectric layers; a capacitor contact disposed in the substrate and protruding from the first dielectric layer of the stack of dielectric layers; and a landing pad disposed over the capacitor contact.

Another aspect of the present disclosure provides a method of fabricating a semiconductor device including providing a substrate having an active region; providing a recess gate structure in the active region of the substrate; forming a stack of dielectric layers over the substrate; forming a bit line contact on the substrate and laterally surrounded by the stack of dielectric layers; forming a capacitor contact in the substrate and protruding from the substrate; and forming a landing pad over the capacitor contact. The capacitor contact comprises a contact structure, a barrier layer, and a barrier spacer.

Another aspect of the present disclosure provides a method of fabricating a semiconductor device including providing substrate having an active region; providing a recess gate structure in the active region of the substrate; forming a stack of dielectric layers over the substrate; forming a bit line contact on the substrate and laterally surrounded by the stack of dielectric layers; forming a capacitor contact in the substrate and protruding from a top surface of the substrate; and forming a landing pad disposed over the capacitor contact.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate having an active region;
a recess gate structure disposed in the substrate and intersecting the active region;
a bit line contact comprising a polysilicon stack and disposed on the substrate;
a conductive pillar disposed over the substrate and electrically connected to the active region;
a landing pad disposed on the conductive pillar and electrically connected to the conductive pillar; and
a stack of dielectric layers disposed over the substrate and laterally surrounding the bit line contact,
wherein the polysilicon stack comprises a first polysilicon layer and a second polysilicon layer disposed over the first polysilicon layer, wherein the second polysilicon layer is in direct contact with the stack of dielectric layers.

2. The semiconductor device of claim 1, further comprising:
a bit line disposed over the bit line contact and laterally surrounded by the stack of dielectric layers.

3. The semiconductor device of claim 1, wherein the recess gate structure comprises:
a gate insulating layer conformally formed in a recess disposed in the substrate;
a word line formed on the gate insulating layer and in the recess; and
a capping layer formed on the word line and in the recess.

4. The semiconductor device of claim 3, wherein the gate insulating layer is formed of silicon oxide or a high-k dielectric material having a dielectric constant greater than 3.9; the word line is formed of polysilicon, tungsten, nickel silicide, platinum silicide, titanium silicide, molybdenum silicide, cobalt silicide, tantalum silicide, tungsten silicide; and the capping layer is formed of silicon oxide, silicon nitride, or silicon oxynitride.

5. The semiconductor device of claim 1, wherein the bit line contact is surrounded by the stack of dielectric layers and further comprises a contact structure disposed directly over the polysilicon stack.

6. The semiconductor device of claim 5, wherein the polysilicon stack of the bit line contact further comprises:
a third polysilicon layer disposed over the second polysilicon layer; and
a fourth polysilicon layer disposed over the third polysilicon layer.

7. The semiconductor device of claim 6, wherein the first polysilicon layer and the third polysilicon layer are undoped, and the second polysilicon layer and the fourth polysilicon layer are doped.

8. The semiconductor device of claim 7, wherein a dopant concentration of the second polysilicon layer is greater than a dopant concentration of the fourth polysilicon layer.

9. The semiconductor device of claim 5, wherein the contact structure of the bit line contact further comprises:
a barrier layer disposed over the polysilicon stack; and
a conductive layer disposed over and surrounded by the barrier layer.

10. The semiconductor device of claim 9, wherein a top surface of the barrier layer is substantially coplanar with a top surface of the conductive layer.

11. The semiconductor device of claim 9, wherein the barrier layer includes titanium (Ti), titanium nitride (TiN), or a combination thereof; and the conductive layer includes tungsten (W).

12. The semiconductor device of claim 1, wherein the conductive pillar includes a lower portion disposed on the stack of dielectric layers and an upper portion disposed over the lower portion, wherein a width of the upper portion is greater than a width of the lower portion.
